(19) United States
(12) Patent Application Publication
(10) Pub. No.: US 2024/0429672 A1
(43) Pub. Date: Dec. 26, 2024

(54) LASER APPARATUS AND METHOD FOR MANUFACTURING ELECTRONIC DEVICES

(71) Applicant: Gigaphoton Inc., Tochigi (JP)

(72) Inventors: Seiji NOGIWA, Oyama-shi (JP); Osamu WAKABAYASHI, Oyama-shi (JP)

(73) Assignee: Gigaphoton Inc., Tochigi (JP)

(21) Appl. No.: 18/827,268

(22) Filed: Sep. 6, 2024

Related U.S. Application Data
(63) Continuation of application No. PCT/JP2022/017923, filed on Apr. 15, 2022.

(51) Int. Cl. H01S 3/091; G03F 7/00; H01S 3/094; H01S 3/225; H01S 5/00; H01S 5/125

(52) U.S. Cl. CPC H01S 3/0912; G03F 7/70025; G03F 7/70041; G03F 7/70508; G03F 7/70516; G03F 7/70525; G03F 7/70575; H01S 3/094076; H01S 3/225; H01S 5/0092; H01S 5/125

(57) ABSTRACT

A laser apparatus includes a first semiconductor laser outputting first continuous-wave laser light; a first amplifier a wavelength conversion system outputting second pulse laser light; an excimer amplifier amplifying the second pulse laser light; a monitor module; and a processor calculating a center wavelength being an average of a measured value of the wavelength of the third pulse laser light output at the first target wavelength and a measured value of the wavelength thereof output at the second target wavelength, calculating a wavelength difference of the measurement values, calculating an average current value of a current flowing through the first semiconductor laser, calculating a current value difference such that a difference between a target wavelength difference and the wavelength difference decreases, and calculating a first current value at the first target wavelength and a second current value at the second target wavelength to control the first semiconductor laser.

### CROSS-REFERENCE TO RELATED APPLICATIONS

The present application is a continuation application of International Application No. PCT/JP2022/017923, filed on Apr. 15, 2022, the entire contents of which are hereby incorporated by reference.

### BACKGROUND

### 1. Technical Field

The present disclosure relates to a laser apparatus and a method for manufacturing electronic devices.

### 2. Related Art

In recent years, a semiconductor exposure apparatus is required to improve the resolution thereof as semiconductor integrated circuits are increasingly miniaturized and highly integrated. To this end, reduction in the wavelength of light emitted from a light source for exposure is underway. For example, a KrF excimer laser apparatus, which outputs laser light having a wavelength of about 248 nm, and an ArF excimer laser apparatus, which outputs laser light having a wavelength of about 193 nm, are used as a gas laser apparatus for exposure.

The light from KrF and ArF excimer laser apparatuses undergoing spontaneous laser oscillation has a wide spectral linewidth ranging from 350 to 400 pm. A projection lens made of a material that transmits ultraviolet light, such as the KrF and ArF laser light, therefore produces chromatic aberrations in some cases. As a result, the resolution of the projection lens may decrease. To avoid the decrease in the resolution, the spectral linewidth of the laser light output from the gas laser apparatus needs to be narrow enough to make the chromatic aberrations negligible. To this end, a line narrowing module (LNM) including a line narrowing element (such as etalon or grating) is provided in some cases in a laser resonator of the gas laser apparatus to narrow the spectral linewidth. A gas laser apparatus providing a narrowed spectral linewidth is hereinafter referred to as a narrowed-line gas laser apparatus.

### CITATION LIST

### Patent Literature

[PTL 1] U.S. Patent application Publication No. 2021/0226414
[PTL 2] WO2021/015919
[PTL 3] WO2020/231946

### SUMMARY

A laser apparatus according to an aspect of the present disclosure includes a first wavelength variable semiconductor laser configured to output first continuous-wave laser light; a first amplifier configured to pulse and amplify the first laser light and output first pulse laser light; a wavelength conversion system configured to convert a wavelength of the first pulse laser light and output resultant second pulse laser light; an excimer amplifier configured to amplify the second pulse laser light and output resultant third pulse laser light; a monitor module configured to measure a wavelength of the third pulse laser light; and a processor configured to change a target wavelength of the third pulse laser light alternately to a first target wavelength and a second target wavelength longer than the first target wavelength, calculate a center wavelength that is an average of a measured value of the wavelength of the third pulse laser light output at the first target wavelength and a measured value of the wavelength of the third pulse laser light output at the second target wavelength and a wavelength difference that is a difference between the measured values, calculate an average current value that is an average of a first current value of a current flowing through the first semiconductor laser operating at the first target wavelength and a second current value of the current flowing through the first semiconductor laser operating at the second target wavelength in such a way that a difference between the center wavelength and a target center wavelength that is an average of the first target wavelength and the second target wavelength decreases, calculate a current value difference that is a difference between the first current value and the second current value in such a way that the wavelength difference and a target wavelength difference that is a difference between the first target wavelength and the second target wavelength decreases, and calculate the first current value and the second current value from the average current value and the current value difference and control the first semiconductor laser in such a way that the first current value is used when the third pulse laser light is output at the first target wavelength and the second current value is used when the third pulse laser light is output at the second target wavelength.

A method for manufacturing electronic devices according to another aspect of the present disclosure includes generating third pulse laser light by using a laser apparatus; outputting the third pulse laser light to an exposure apparatus; and exposing a photosensitive substrate to the third pulse laser light in the exposure apparatus to manufacture the electronic devices, the laser apparatus including a first wavelength variable semiconductor laser configured to output first continuous-wave laser light, a first amplifier configured to pulse and amplify the first laser light and output first pulse laser light, a wavelength conversion system configured to convert a wavelength of the first pulse laser light and output resultant second pulse laser light, an excimer amplifier configured to amplify the second pulse laser light and output the third pulse laser light, a monitor module configured to measure a wavelength of the third pulse laser light, and a processor configured to change a target wavelength of the third pulse laser light alternately to a first target wavelength and a second target wavelength longer than the first target wavelength, calculate a center wavelength that is an average of a measured value of the wavelength of the third pulse laser light output at the first target wavelength and a measured value of the wavelength of the third pulse laser light output at the second target wavelength and a wavelength difference that is a difference between the measured values, calculate an average current value that is an average of a first current value of a current flowing through the first semiconductor laser operating at the first target wavelength and a second current value of the current flowing through the first semiconductor laser operating at the second target wavelength in such a way that a difference between the center wavelength and a target center wavelength that is an average of the first target wavelength and the second target wavelength decreases, calculate a current value difference that is a difference between the first current value and the second current value in such a way that a difference between the wavelength difference and a target wavelength difference that is a difference between the first target wavelength and the second target wavelength decreases, and calculate the first current value and the second current value from the average current value and the current value difference and control the first semiconductor laser in such a way that the first current value is used when the third pulse laser light is output at the first target wavelength and the second current value is used when the third pulse laser light is output at the second target wavelength.

A laser apparatus according to another aspect of the present disclosure includes: a first wavelength variable semiconductor laser configured to output first continuous-wave laser light; a first amplifier configured to pulse and amplify the first laser light and output first pulse laser light; a wavelength conversion system configured to convert a wavelength of the first pulse laser light and output resultant second pulse laser light; an excimer amplifier configured to amplify the second pulse laser light and output resultant third pulse laser light; a monitor module configured to measure a wavelength of the third pulse laser light; and a processor configured to change a target wavelength of the third pulse laser light alternately to a first target wavelength and a second target wavelength longer than the first target wavelength, calculate a center wavelength that is an average of a measured value of the wavelength of the third pulse laser light output at the first target wavelength and a measured value of the wavelength of the third pulse laser light output at the second target wavelength and a wavelength difference that is a difference between the measured values, calculate a current value difference that is a difference between a first current value of a current flowing through the first semiconductor laser operating at the first target wavelength and a second current value of the current flowing through the first semiconductor laser operating at the second target wavelength in such a way that a difference between the wavelength difference and a target wavelength difference that is a difference between the first target wavelength and the second target wavelength decreases, calculate the first current value and the second current value from a reference current value of the current flowing through the first semiconductor laser and the current value difference and control the first semiconductor laser in such a way that the first current value is used when the third pulse laser light is output at the first target wavelength and the second current value is used when the third pulse laser light is output at the second target wavelength, and control a temperature of the first semiconductor laser in such a way that the center wavelength becomes a target center wavelength that is an average of the first target wavelength and the second target wavelength.

A method for manufacturing electronic devices according to another aspect of the present disclosure includes generating third pulse laser light by using a laser apparatus; outputting the third pulse laser light to an exposure apparatus; and exposing a photosensitive substrate to the third pulse laser light in the exposure apparatus to manufacture the electronic devices, the laser apparatus including a first wavelength variable semiconductor laser configured to output first continuous-wave laser light, a first amplifier configured to pulse and amplify the first laser light and output first pulse laser light, a wavelength conversion system configured to convert a wavelength of the first pulse laser light and output resultant second pulse laser light, an excimer amplifier configured to amplify the second pulse laser light and output the third pulse laser light, a monitor module configured to measure a wavelength of the third pulse laser light, and a processor configured to change a target wavelength of the third pulse laser light alternately to a first target wavelength and a second target wavelength longer than the first target wavelength, calculate a center wavelength that is an average of a measured value of the wavelength of the third pulse laser light output at the first target wavelength and a measured value of the wavelength of the third pulse laser light output at the second target wavelength and a wavelength difference that is a difference between the measured values, calculate a current value difference that is a difference between a first current value of a current flowing through the first semiconductor laser operating at the first target wavelength and a second current value of the current flowing through the first semiconductor laser operating at the second target wavelength in such a way that a difference between the wavelength difference and a target wavelength difference that is a difference between the first target wavelength and the second target wavelength decreases, calculate the first current value and the second current value from a reference current value of the current flowing through the first semiconductor laser and the current value difference and control the first semiconductor laser in such a way that the first current value is used when the third pulse laser light is output at the first target wavelength and the second current value is used when the third pulse laser light is output at the second target wavelength, and control a temperature of the first semiconductor laser in such a way that the center wavelength becomes a target center wavelength that is an average of the first target wavelength and the second target wavelength.

### BRIEF DESCRIPTION OF DRAWINGS

Embodiments of the present disclosure will be described below only by way of example with reference to the accompanying drawings.

FIG. 1 is a graph showing an example of a two-wavelength spectrum applied to two-wavelength exposure.

FIG. 2 schematically shows the configuration of an exposure apparatus connected to a laser apparatus.

FIG. 3 is a top view schematically showing the configuration of a laser apparatus according to Comparative Example.

FIG. 4 is a side view schematically showing the configuration of the laser apparatus according to Comparative Example.

FIG. 5 schematically shows the configuration of a laser apparatus according to a first embodiment.

FIG. 6 is a flowchart showing an example of processes carried out by a laser control processor in the first embodiment.

FIG. 7 is a graph showing an example of the relationship between the number of pulses and the wavelength of excimer laser light.

FIG. 8 is a graph showing an example of the relationship between the number of pulses and a current value of a current flowing through a semiconductor laser.

FIG. 9 schematically shows the configuration of a semiconductor laser system.

FIG. 10 is a graph showing an example of the two-wavelength spectrum produced by two-wavelength control.

FIG. 11 is a flowchart showing a first example of the control of the temperature of the semiconductor laser performed by the laser control processor.

FIG. 12 is a graph showing an example of the relationship between a set temperature of the semiconductor laser and the wavelength after excimer amplification.

FIG. 13 is a flowchart showing a second example of the control of the temperature of the semiconductor laser performed by the laser control processor.

FIG. 14 schematically shows the configuration of a wavelength conversion system.

FIG. 15 shows graphs showing an example of wavelength conversion efficiency curves for a KBBF crystal and an LBO crystal.

FIG. 16 schematically shows the configuration of a nonlinear crystal temperature adjustment system.

FIG. 17 is a graph showing an example of the relationship between a target center wavelength after the wavelength conversion and a temperature at which the wavelength conversion efficiency is maximized.

FIG. 18 is a flowchart showing an example of control of the wavelength conversion.

FIG. 19 shows graphs showing a first example of the relationship between the wavelength conversion efficiency curves of nonlinear optical crystals and the two-wavelength spectrum.

FIG. 20 shows graphs showing a second example of the relationship between the wavelength conversion efficiency curves of the nonlinear optical crystals and the two-wavelength spectrum.

FIG. 21 is a flowchart showing an example of processes carried out by a laser control processor in a second embodiment.

FIG. 22 is a flowchart showing an example of the control of the temperature of the semiconductor laser performed by the laser control processor in the second embodiment.

FIG. 23 schematically shows the configuration of a variation of a solid-state seeder.

FIG. 24 schematically shows the configuration of a distributed Bragg reflector semiconductor laser system.

FIG. 25 schematically shows the configuration of a sampled grating distributed Bragg reflector semiconductor laser system.

FIG. 26 schematically shows the configuration of the exposure apparatus.

### DETAILED DESCRIPTION

### Contents

1. Description of terms
2. Comparative Example
2.1 Overview of exposure system
2.1.1 Configuration
2.1.2 Operation
2.2 Laser apparatus according to Comparative Example
2.2.1 Configuration
2.2.2 Operation
3. Problems
4. First Embodiment
4.1 Description of laser apparatus
4.1.1 Configuration
4.1.2 Operation
4.1.2.1 Operation in normal control
4.1.2.2 Operation in two-wavelength control
4.1.3 Effects and advantages
4.1.4 Others
4.2 Example of semiconductor laser system
4.2.1 Configuration
4.2.2 Operation
4.2.3 Others
4.3 Example of control of temperature of semiconductor laser
4.3.1 First example of flowchart
4.3.2 Second example of flowchart
4.3.3 Effects and advantages
4.4 Example of wavelength conversion system
4.4.1 Configuration
4.4.2 Operation
4.5 Nonlinear crystal temperature adjustment system
4.5.1 Configuration
4.5.2 Operation
4.5.3 Others
4.6 Method for controlling wavelength conversion system
4.6.1 Example of flowchart
4.6.2 Operation
4.6.3 Effects and advantages
5. Second Embodiment
5.1 Configuration
5.2 Operation
5.3 Effects and advantages
5.4 Others
6. Third Embodiment
6.1 Configuration
6.2 Operation
6.3 Others
7. Fourth Embodiment
7.1 Configuration
7.2 Operation
7.3 Others
7.4 Effects and advantages
8. Fifth Embodiment
8.1 Configuration
8.2 Operation
8.3 Effects and advantages
9. Method for manufacturing electronic devices
10. Others

Embodiments of the present disclosure will be described below in detail with reference to the drawings. The embodiments described below show some examples of the present disclosure and are not intended to limit the contents of the present disclosure. Furthermore, all configurations and operations described in the embodiments are not necessarily essential as configurations and operations in the present disclosure. The same elements have the same reference characters, and no redundant description of the same elements will be made.

### 1. Description of Terms

In the present specification, “two-wavelength exposure” refers to causing a laser apparatus to undergo laser oscillation alternately at wavelengths λ_{S} and λ_{L} on a pulse basis to perform the two-wavelength exposure.

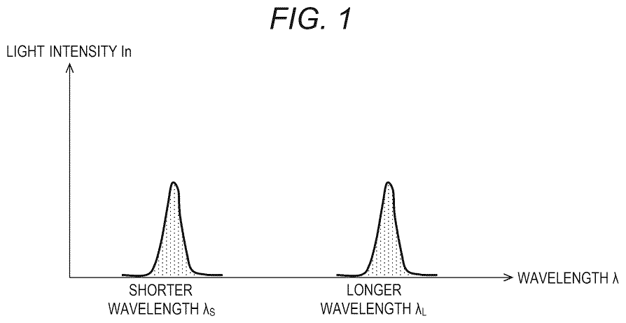

FIG. 1 is a graph for showing two-wavelength parameters in two-wavelength exposure. In FIG. 1, the horizontal axis represents a wavelength λ, and the vertical axis represents a light intensity In. In the two-wavelength exposure, the shorter wavelength is called λ_{S}, and the longer wavelength is called λ_{L}, as shown in FIG. 1.

A center wavelength λ_{C} of a two-wavelength spectrum is expressed by Expression (1) below.

$$λ c = ( {λ}_{L} + {λ}_{S} ) / 2 \qquad ( 1 )$$

A difference Δλ between the wavelengths of the two-wavelength spectrum is expressed by Expression (2) below.

$$Δ λ = {λ}_{L} - {λ}_{S} \qquad ( 2 )$$

### 2. Comparative Example

### 2.1 Overview of Exposure System

### 2.1.1 Configuration

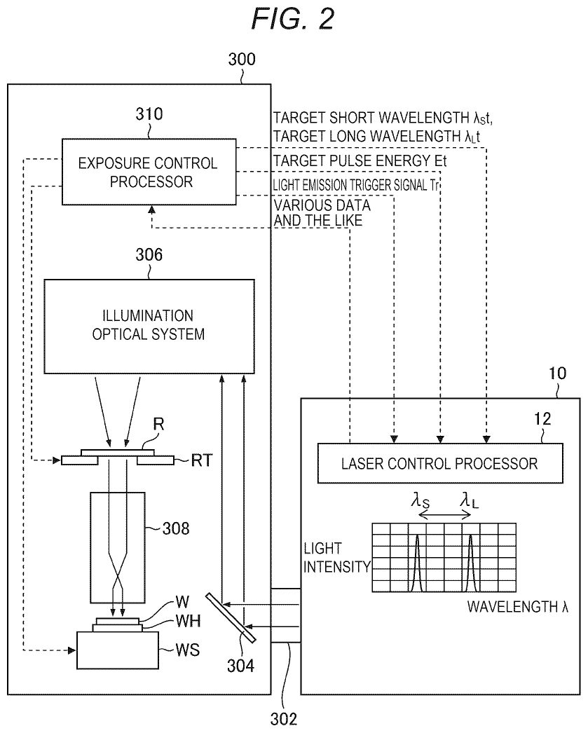

FIG. 2 schematically shows the configuration of an exposure system. The exposure system includes a laser apparatus 10 and an exposure apparatus 300. The laser apparatus 10 includes a laser control processor 12. The processor in the present specification is a processing apparatus including a storage that stores a control program and a CPU (central processing unit) that executes the control program. The processor is particularly configured or programmed to carry out a variety of processes described in the present disclosure.

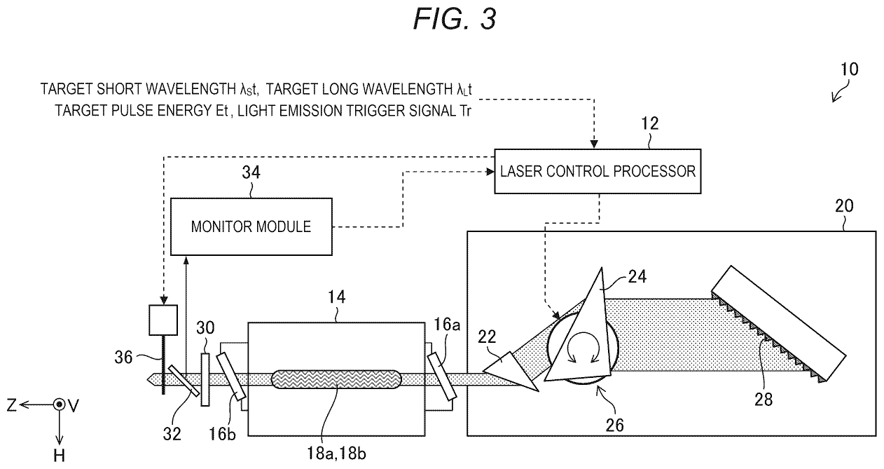

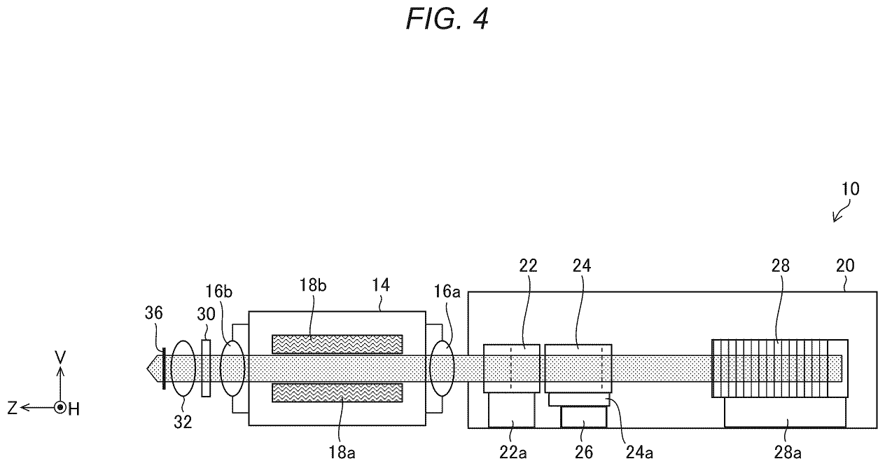

The laser apparatus 10 is configured to output pulse laser light having a changeable oscillation wavelength toward the exposure apparatus 300. The configuration of the laser apparatus 10 will be described later (FIGS. 3 and 4).

The exposure apparatus 300 includes a beam delivery unit (BDU) 302, a highly reflective mirror 304, an illumination optical system 306, a reticle stage RT, a projection optical system 308, a wafer stage WS, and an exposure control processor 310. The wafer stage WS is provided with a wafer holder WH, and a wafer W is placed on the wafer holder WH.

The BDU 302 is an optical system that delivers the pulse laser light from the laser apparatus 10 to the exposure apparatus 300. The highly reflective mirror 304 is so disposed that the pulse laser light having passed through the BDU 302 enters the illumination optical system 306.

The illumination optical system 306 is an optical system that shapes the beam of the pulse laser light incident from the laser apparatus 10 and guides the shaped pulse laser light to a reticle R placed on the reticle stage RT. The illumination optical system 306 shapes the beam of the pulse laser light in such a way that the pulse laser light has an approximately rectangular beam cross-sectional shape and has an approximately uniform light intensity distribution, and illuminates a reticle pattern of the reticle R with the shaped pulse laser light. The projection optical system 308 performs reduction projection on the pulse laser light having passed through the reticle R to bring the pulse laser light into focus on the wafer W on the wafer holder WH. The wafer W is a photosensitive substrate, such as a semiconductor wafer coated with a photoresist film.

The exposure control processor 310 is a processing apparatus including a storage that stores a control program, and a CPU that executes the control program. The exposure control processor 310 oversees control of the exposure apparatus 300. The exposure control processor 310 is connected to the reticle stage RT and the wafer stage WS. The exposure control processor 310 is further connected to the laser control processor 12.

### 2.1.2 Operation

The exposure control processor 310 transmits a variety of parameters including a target short wavelength λ_{S}t, a target long wavelength λ_{L}t, and target pulse energy Et, and a light emission trigger signal Tr to the laser control processor 12. The laser control processor 12 controls the laser apparatus 10 in accordance with the parameters and the signal. That is, the laser control processor 12 controls the oscillation wavelength by periodically changing the target wavelength in such a way that the wavelength λ of the pulse laser light output from the laser apparatus 10 becomes the target short wavelength λ_{S}t or the target long wavelength λ_{L}t, controls excitation intensity in such a way that pulse energy E becomes the target pulse energy Et, and causes the laser apparatus 10 to output the pulse laser light in accordance with the light emission trigger signal Tr.

The laser apparatus 10 thus performs the two-wavelength oscillation at the target short wavelength λ_{S}t and the target long wavelength λ_{L}t at the target pulse energy Et, and outputs the pulse laser light in accordance with the light emission trigger signal Tr.

Furthermore, the laser control processor 12 transmits a variety of data and other pieces of information to the exposure control processor 310. The variety of data include measured data such as the wavelength and pulse energy of the pulse laser light output in accordance with the light emission trigger signal Tr.

The exposure control processor 310 synchronously moves the reticle stage RT and the wafer holder WH on the wafer stage WS in parallel in directions opposite to each other. The wafer W is thus exposed to the pulse laser light having reflected the reticle pattern.

To form a 3D NAND pattern or a contact hole pattern, the exposure is so performed that the waveform of an integrated spectrum is that of a desired two-wavelength spectrum to ensure the depth of focus.

### 2.2 Laser Apparatus According to Comparative Example

### 2.2.1 Configuration

FIGS. 3 and 4 are a top view and a side view schematically showing the configuration of the laser apparatus 10 according to Comparative Example. Comparative Example in the present disclosure is an aspect that the applicant is aware of as known only by the applicant, and is not a publicly known example that the applicant is self-aware of.

The laser apparatus 10 shown in FIGS. 3 and 4 is a single-wavelength oscillation, narrowed-line excimer laser apparatus, and includes the laser control processor 12, a chamber 14, an LNM 20, an output coupling mirror 30, a beam splitter 32, a monitor module 34, and a light-exiting-port shutter 36.

The LNM 20 includes a first prism 22, a second prism 24, a rotary stage 26, and a grating 28. The first prism 22, the second prism 24, and the grating 28 are supported by holders 22a, 24a, and 28a, respectively. The first prism 22 and the second prism 24 are disposed so as to function as a beam expander. The grating 28 is disposed in the Littrow arrangement, which causes the angle of incidence of the light beam incident from the second prism 24 on the grating 28 to be equal to the angle of diffraction of the diffracted light having a desired wavelength.

The second prism 24 is disposed on the rotary stage 26 via the holder 24a. The rotary stage 26 is a stage being rotatable by a piezoelectric device that is not shown and being quickly responsive to some extent. The second prism 24 is disposed so as to change the angle of incidence of the light to be incident on the grating 28 when the rotary stage 26 rotates the second prism 24 around a V-axis.

The output coupling mirror 30 and the LNM 20 constitute an optical resonator. The chamber 14 is disposed in the optical path of the optical resonator.

The chamber 14 includes windows 16a and 16b and a pair of electrodes 18a and 18b. A laser gas is supplied into the chamber 14 from a gas supply apparatus that is not shown. The laser gas may be an excimer laser gas containing, for example, an Ar or Kr gas as a rare gas, an F₂ gas as a halogen gas, and an Ne gas as a buffer gas.

The electrodes 18a and 18b are so disposed in the chamber 14 that the electrodes face each other in the V direction, and that the longitudinal direction of the electrodes 18a and 18b coincides with the optical path of the optical resonator. The laser apparatus 10 further includes a pulse power module (PPM) and a charger neither of which is shown. The PPM includes a switch and a charging capacitor and is connected to the electrode 18b via feedthroughs in an electrically insulating member that is not shown. The electrode 18a is connected to the chamber 14, which is grounded. The charger charges the charging capacitor of the PPM in accordance with an instruction from the laser control processor 12.

The windows 16a and 16b are so disposed that the pulse laser light having been excited and amplified by the discharge between the electrodes 18a and 18b passes through the windows.

The output coupling mirror 30 is coated with a film that reflects part of the pulse laser light and transmits another part thereof. The beam splitter 32 is disposed in the optical path of the pulse laser light output via the output coupling mirror 30. The beam splitter 32 is so disposed that light reflected off the beam splitter 32 enters the monitor module 34. Note that the beam splitter 32 may be incorporated in the monitor module 34.

The monitor module 34 includes a pulse energy measuring device and a spectrum detector. The pulse energy measuring device includes a photosensor that is not shown. The photosensor may be a photodiode that is resistant to ultraviolet light and has an excellent high-speed response. The spectrum detector may detect wavelengths, for example, with an etalon spectrometer.

The light-exiting-port shutter 36 is disposed in the optical path of the pulse laser light output from the laser apparatus 10 to the exterior thereof and can block and unblock the pulse laser light toward the exterior. The pulse laser light having passed through the beam splitter 32 exits out of the laser apparatus 10 via the light-exiting-port shutter 36, and enters the exposure apparatus 300.

### 2.2.2 Operation

The laser control processor 12 acquires the variety of parameters including the target short wavelength λ_{S}t, the target long wavelength Alt, and the target pulse energy Et. The laser control processor 12 further receives the light emission trigger signal Tr.

The laser control processor 12 controls a voltage to be applied to the electrode 18b based on the received target pulse energy Et. The control of the voltage includes feedback control based on the pulse energy measured by the monitor module 34.

A pulse-shaped high voltage is applied from the PPM to the electrode 18b under the control performed by the laser control processor 12. When the high voltage is applied to the electrode 18b, discharge occurs in a discharge space between the electrodes 18a and 18b. The energy of the discharge excites the laser gas in the chamber 14, and the state of the excited laser gas transitions to a high energy level. Thereafter, when the excited laser gas transitions to a low energy level, the laser gas emits light having a wavelength according to the difference between the energy levels.

The light generated in the chamber 14 exits as a light beam out of the chamber 14 via the windows 16a and 16b. The beam width of the light beam having exited via the window 16a is enlarged by the first prism 22 and the second prism 24 in a plane parallel to an HZ plane, which is a plane perpendicular to the V-axis. The light beam having passed through the first prism 22 and the second prism 24 is incident on the grating 28.

The light beam incident on the grating 28 is reflected off and diffracted by multiple grooves of the grating 28 in the direction according to the wavelength of the light.

The first prism 22 and the second prism 24 reduce the beam width of the light beam having returned from the grating 28 in the plane parallel to the HZ plane, and cause the resultant light beam to return into the chamber 14 via the window 16a.

The output coupling mirror 30 transmits part of the light beam having exited via the window 16b and reflects another part of the light beam back into the chamber 14.

The light beam having exited out of the chamber 14 thus travels back and forth between the LNM 20 and the output coupling mirror 30. The light beam is amplified whenever passing through the discharge space in the chamber 14. The light beam undergoes the line narrowing operation whenever deflected back by the LNM 20. The light beam thus having undergone the laser oscillation and the line narrowing operation is output as the pulse laser light via the output coupling mirror 30.

The monitor module 34 measures the pulse energy and the wavelength of the pulse laser light reflected off the beam splitter 32, and transmits the measured pulse energy and wavelength to the laser control processor 12.

The pulse laser light having passed through the beam splitter 32 is output from the laser apparatus 10 via the light-exiting-port shutter 36.

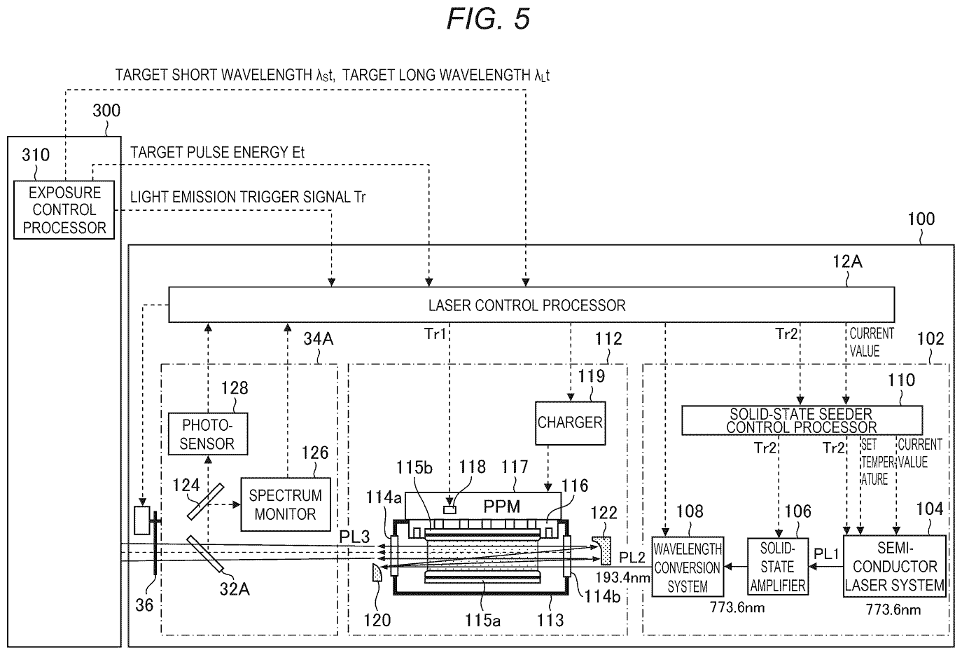

The laser control processor 12 changes the oscillation wavelength by causing the rotary stage 26, at which the second prism 24 is disposed, to control the angle of incidence of the light to be incident on the grating 28. The laser control processor 12 measures the wavelength of the pulse laser light with a spectrum monitor 126 (see FIG. 5) in the monitor module 34, and controls the rotary stage 26 in such a way that the oscillation wavelength alternately changes to two target wavelengths (λ_{S}t and λ_{L}t) on a pulse basis. Performing the control described above controls the oscillation wavelength of the pulse laser light output from the laser apparatus 10 to the target short wavelength λ_{S}t and the target long wavelength λ_{L}t on a pulse basis.

### 3. Problems

To generate a two-wavelength exposure spectral waveform, it has been necessary to change the wavelength with high precision on a pulse basis. Furthermore, when the second prism 24 or any other optical element of the LNM 20 is rotated by the rotary stage 26 on a pulse basis, it has been difficult, as the repetition frequency (4 kHz or higher) of the laser apparatus 10 increases, to stabilize the wavelength of the output pulse laser light at each of the two target wavelengths (λ_{S}t and λ_{L}t) with high precision.

### 4. First Embodiment

### 4.1 Description of Laser Apparatus

### 4.1.1 Configuration

FIG. 5 schematically shows the configuration of a laser apparatus 100 according to a first embodiment. FIG. 5 shows a case where the laser apparatus 100 includes a solid-state seeder 102 and an excimer amplifier 112, and the spectrum of the pulse laser light output from the laser apparatus 100 is a two-wavelength spectrum with two target wavelengths being the target short wavelength λ_{S}t and the target long wavelength λ_{L}t.

The laser apparatus 100 includes a laser control processor 12A, the solid-state seeder 102 as a master oscillator (MO), the excimer amplifier 112 as a power amplifier (PA), a monitor module 34A, and the light-exiting-port shutter 36.

The solid-state seeder 102 includes a semiconductor laser system 104 which outputs pulse laser light, a solid-state amplifier 106 which amplifies the pulse laser light, a wavelength conversion system 108, and a solid-state seeder control processor 110.

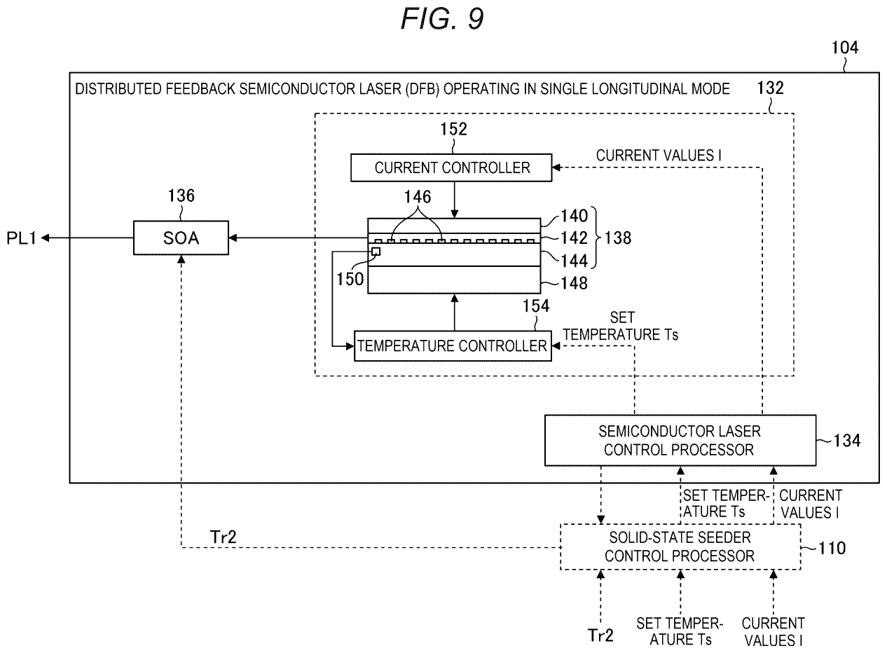

The configuration of the semiconductor laser system 104 will be described later in detail (see FIG. 9). The semiconductor laser system 104 includes, for example, a semiconductor laser 132 (see FIG. 9) which outputs a continuous wave (CW) laser light having a wavelength of about 773.6 nm, and a semiconductor optical amplifier (SOA) 136 (see FIG. 9). The semiconductor laser 132 can change the oscillation wavelength at which it operates by controlling the temperature of a semiconductor laser device 138 (see FIG. 9) and/or the value of a current flowing through the semiconductor laser device 138.

The SOA 136 pulses and amplifies the CW laser light output from the semiconductor laser 132. The SOA 136, through which a pulse current is caused to flow, pulses and amplifies the CW laser light and outputs pulse laser light PL1 having undergone the pulsing and amplification.

The solid-state amplifier 106 includes a titanium-sapphire crystal and a pumping pulse laser neither of which is shown. The titanium sapphire crystal is disposed in the optical path of the pulse laser light PL1 having undergone the pulsing and amplification performed by the SOA 136. The pumping pulse laser is a laser apparatus that outputs second harmonic of the laser light from a YLF laser. YLF (yttrium lithium fluoride) is a solid-state laser crystal expressed by a chemical formula LiYF₄.

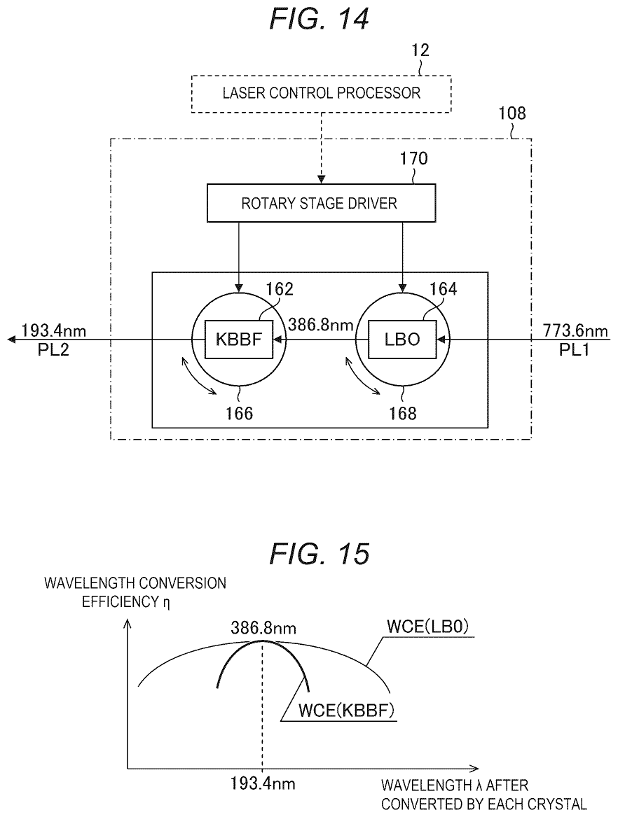

The wavelength conversion system 108 is a wavelength conversion system including a nonlinear crystal, and converts the wavelength of pulse laser light incident thereon to generate resultant fourth harmonic light. The configuration of the wavelength conversion system 108 will be described later (see FIG. 14).

The solid-state seeder control processor 110 controls the semiconductor laser system 104 and the solid-state amplifier 106 based on inputs from the laser control processor 12A.

The excimer amplifier 112 includes a chamber 113, a pulse power module (PPM) 117, a charger 119, a convex mirror 120, and a concave mirror 122. The chamber 113 includes windows 114a and 114b, a pair of electrodes 115a and 115b, and an electrically insulating member 116. For example, an ArF laser gas containing an Ar gas, an F₂ gas, and an Ne gas are introduced into the chamber 113.

The PPM 117 includes a switch 118 and a charging capacitor that is not shown. The charger 119 retains electrical energy to be supplied to the PPM 117. The charger 119 is connected to the charging capacitor. The PPM 117 is connected to the electrode 115b in the chamber 113 via feedthroughs in the electrically insulating member 116. The electrode 115a is connected to ground potential.

The convex mirror 120 and the concave mirror 122 are so disposed that pulse laser light PL2 output from the wavelength conversion system 108 passes through the discharge space between the electrodes 115a and 115b three times for beam expansion.

The monitor module 34A includes beam splitters 32A and 124, the spectrum monitor 126, and a photosensor 128. The beam splitter 32A is so disposed in the optical path of pulse laser light PL3 output from the excimer amplifier 112 that the pulse laser light reflected off the beam splitter 32A is incident on the beam splitter 124. The beam splitter 32A may be disposed outside the monitor module 34A, as the beam splitter 32 shown in FIG. 3.

The beam splitter 124 is so disposed that the pulse laser light PL3 reflected off the beam splitter 124 enters the spectrum monitor 126, and that the pulse laser light PL3 having passed through the beam splitter 124 enters the photosensor 128.

The spectrum monitor 126 monitors the spectrum of the pulse laser light PL3 incident thereon and detects the wavelength of the incident pulse laser light PL3. The spectrum monitor 126 may, for example, be an etalon spectrometer. An etalon spectrometer includes a diffuser plate that diffuses sample light, an etalon, a light collection lens disposed on the light exiting side of the etalon, and a photodiode array disposed at the focal plane of the light collection lens to detect the pattern of interference fringes, and can detect the wavelength of the pulse laser light by measuring the diameters of the interference fringes.

The photosensor 128 is so disposed that the pulse laser light having passed through the beam splitter 124 is incident on the photosensor 128. The photosensor 128 detects the pulse energy of the pulse laser light incident thereon. The photosensor 128 may, for example, be a photodiode.

### 4.1.2 Operation

### 4.1.2.1 Operation in Normal Control

The semiconductor laser device 138 outputs continuous-wave laser light having the wavelength of about 773.6 nm. Thereafter, when the pulse current is caused to flow through the SOA 136 at the timing when a trigger signal Tr2 is input, pulsing and amplification is performed, so that the pulse laser light PL1 is output. The pulse laser light PL1 is an example of the “first pulse laser light” in the present disclosure.

The pulse laser light PL1 is further amplified by the solid-state amplifier 106.

The wavelength conversion system 108 converts the pulse laser light PL1 amplified by the solid-state amplifier 106 into fourth harmonic light having a wavelength of about 193.4 nm, and outputs the pulse laser light PL2. The pulse laser light PL2 is an example of the “second pulse laser light” in the present disclosure. The fourth harmonic light produced by the wavelength conversion system 108 is an example of the “first harmonic light” in the present disclosure.

The range over which the wavelength of the pulse laser light PL2 output from the solid-state seeder 102 is variable is from about 193.2 nm to 193.5 nm, which is the wavelength band over which the excimer amplifier 112 performs the amplification.

A trigger signal Tr1 is input to the switch 118 of the PPM 117, and the trigger signal Tr2 is input to the SOA 136 and the pumping pulse laser so that discharge occurs in synchronization with the timing when the pulse laser light PL2 output from the solid-state seeder 102 enters the discharge space in the chamber 113 of the excimer amplifier 112.

As a result, the pulse laser light PL2 output from the solid-state seeder 102 undergoes three-pass amplification performed by the excimer amplifier 112. The excimer amplifier 112 outputs amplified pulse laser light PL3. The pulse laser light PL3 is an example of the “third pulse laser light” in the present disclosure.

The pulse laser light PL3 amplified by the excimer amplifier 112 is sampled by the beam splitter 32A of the monitor module 34A, which then measures the pulse energy E and the wavelength λ.

The laser control processor 12A and the solid-state seeder control processor 110 control the oscillation wavelength at which the semiconductor laser 132 of the semiconductor laser system 104 performs laser oscillation in such a way that the wavelength λ of the pulse laser light PL3 output from the excimer amplifier 112 and measured by the monitor module 34A approaches a target value.

The laser control processor 12A and the solid-state seeder control processor 110 further control a charging voltage of the charger 119 in such a way that the pulse energy E of the pulse laser light PL3 output from the excimer amplifier 112 and measured by the monitor module 34A approaches a target value.

### 4.1.2.2 Operation in Two-Wavelength Control

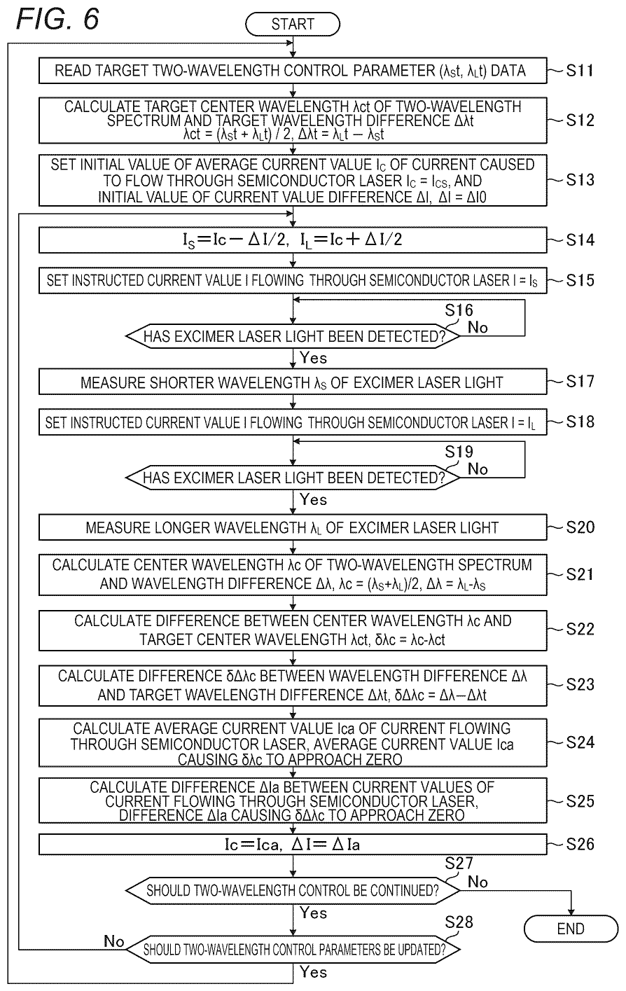

FIG. 6 is a flowchart showing an example of processes carried out by the laser control processor 12A in the first embodiment.

In step S11, the laser control processor 12A reads target two-wavelength control parameter data from the exposure control processor 310. The target two-wavelength control parameter data include the target short wavelength λ_{S}t and the target long wavelength λ_{L}t. The target short wavelength λ_{S}t is an example of the “first target wavelength” in the present disclosure, and the target long wavelength Art is an example of the “second target wavelength” in the present disclosure.

In step S12, the laser control processor 12A calculates a target center wavelength λct of the two-wavelength spectrum and a target wavelength difference Δλt between the two wavelengths by using the expressions below.

$$λ c t = ( {λ}_{S} t + {λ}_{L} t ) / 2 \\ Δλ t = {λ}_{L} t - {λ}_{S} t$$

In step S13, the laser control processor 12A sets initial values of an average current value Ic of the current caused to flow through the semiconductor laser 132 and a current value difference ΔI. The initial value of the average current value Ic is set at a reference current value Ics (Ic=Ics). The reference current value Ics is a current value that allows the semiconductor laser 132 to undergo laser oscillation, and further allows the wavelength and performance of the semiconductor laser device 138 to be maintained even when the current is changed within a range over which the wavelength is changed. The reference current value Ics may be the value at the center of the range over which the current caused to flow through the semiconductor laser 132 can be changed.

The initial value of the current value difference ΔI may be set, for example, at ΔI0. The current value difference ΔI may be set at the initial value ΔI0 on the assumption that the current value difference ΔI is proportional to the wavelength difference Δλ.

In step S14, the laser control processor 12A determines a current value I_{S} to be caused to flow through the semiconductor laser 132 during the short wavelength oscillation and a current value I_{L} to be caused to flow through the semiconductor laser device 138 during the long wavelength oscillation by using the expressions below.

$${I}_{S} = I c - Δ I / 2 \\ {I}_{L} = I c + Δ I / 2$$

That is, the laser control processor 12A subtracts half the current value difference ΔI from the average current value Ic to determine the current value I_{S}, and adds half the current value difference ΔI to the average current value Ic to determine the current value I_{L}.

Thereafter, in step S15, the laser control processor 12A sets an instructed current value I of the current flowing through the semiconductor laser 132 at I_{S}.

In step S16, the laser control processor 12A evaluates whether the excimer laser light has been detected by the monitor module 34A. When the excimer laser light has not been detected (No in step S16), the laser control processor 12A waits until the excimer laser light is detected. When the excimer laser light has been detected (Yes in step S16), the laser control processor 12A proceeds to the process in step S17.

In step S17, the laser control processor 12A measures the shorter wavelength λ_{S} of the excimer laser light based on information from the monitor module 34A.

The processes in steps S15 to S17 are processes of the wavelength measurement and control at the short wavelength.

In step S18, the laser control processor 12A sets the instructed current value I of the current flowing through the semiconductor laser device 138 at I_{L}.

In step S19, the laser control processor 12A evaluates whether the excimer laser light has been detected by the monitor module 34A. When the excimer laser light has not been detected (No in step S19), the laser control processor 12A waits until the excimer laser light is detected. When the excimer laser light has been detected (Yes in step S19), the laser control processor 12A proceeds to the process in step S20.

In step S20, the laser control processor 12A measures the longer wavelength λ_{L} of the excimer laser light based on the information from the monitor module 34.

The processes in steps S18 to S20 are processes of the wavelength measurement and control at the long wavelength.

Thereafter, in step S21, the laser control processor 12A calculates the center wavelength λc of the two-wavelength spectrum and the wavelength difference Δλ between the two wavelengths thereof based on the measured value of the wavelength λ_{S} produced in step S17 and the measured value of the wavelength λ_{L} produced in step S20 by using Expressions (1) and (2).

In step S22, the laser control processor 12A calculates the center wavelength λc of the two-wavelength spectrum and a difference δλc between the center wavelength λc and the target center wavelength of the two-wavelength spectrum by using the expression below.

$$δ λ c = λ c - λ c t$$

In step S23, the laser control processor 12A calculates a difference δΔλc between the wavelength difference Δλ and the target wavelength difference Δλt by using the expressions below.

$$δ Δ λ c = Δ λ - Δ λ t$$

Steps S21 to S23 are processes of evaluating the two-wavelength spectrum.

In step S24, the laser control processor 12A calculates an average current value Ica of the current flowing through the semiconductor laser 132, the average current value Ica causing the difference δλc to approach zero.

In step S25, the laser control processor 12A calculates a difference ΔIa between current values of the current flowing through the semiconductor laser 132, the difference ΔIa causing the difference δΔλc to approach zero.

In step S26, the laser control processor 12A updates the average current value Ic by setting the value of the average current value Ic at Ica determined in step S24, and updates the value of the current value difference ΔI at ΔIa determined in step S25.

Steps S24 to S26 are processes of performing correction calculation of the current value of the current flowing through the semiconductor laser 132 and setting calculated current value based on the result of the evaluation of the two-wavelength spectrum.

In step S27, the laser control processor 12A evaluates whether the two-wavelength control should be continued. When the two-wavelength control should be continued (Yes in step S27), the laser control processor 12A proceeds to the process in step S28. When the two-wavelength control should not be continued (No in step S27), the laser control processor 12A terminates the processes in the flowchart.

In step S28, the laser control processor 12A evaluates whether the two-wavelength control parameters should be updated. When the two-wavelength control parameters should not be updated (No in step S28), the laser control processor 12A returns to the process in step S14. When the two-wavelength control parameters should be updated (Yes in step S28), the laser control processor 12A returns to the process in step S11.

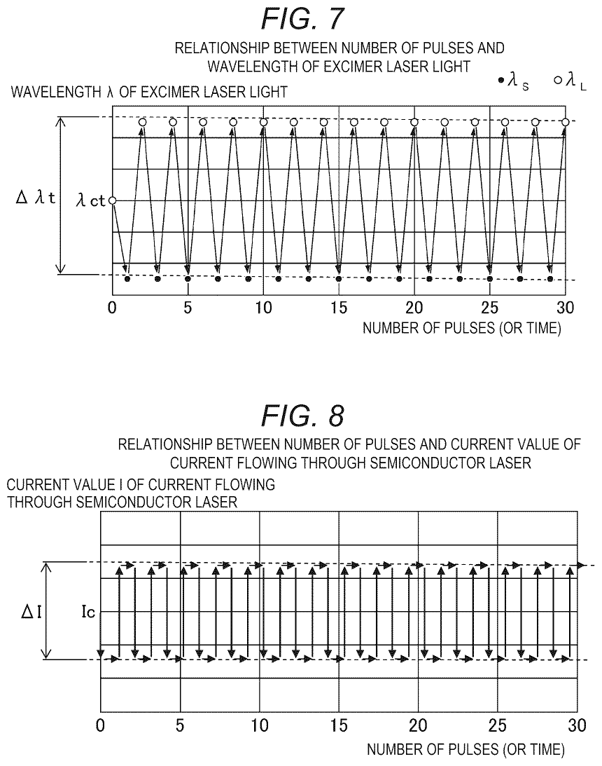

FIG. 7 is a timing chart showing an example of the relationship between the number of pulses and the wavelength of excimer laser light output from the laser apparatus 100. In FIG. 7, the horizontal axis represents the number of pulses (or time), and the vertical axis represents the wavelength. The laser apparatus 100 alternately outputs the excimer laser light having the shorter wavelength λ_{S} and the excimer laser light having the longer wavelength λ_{L} on a pulse basis, as shown in FIG. 7. In the description below, the odd-numbered pulses are pulses of the excimer laser light having the shorter wavelength λ_{S} and the even-numbered pulses are pulses of the excimer laser light having the longer wavelength λ_{L}, but the odd-numbered pulses may be pulses of the excimer laser light having the longer wavelength λ_{L} and the even-numbered pulses may be pulses of the excimer laser light having the shorter wavelength λ_{S}.

The shorter wavelength λ_{S} and the longer wavelength λ_{L} of the excimer laser light output from the laser apparatus 100 may change to the two target wavelengths, the shorter wavelength λ_{S} and the longer wavelength λ_{L}, on a pulse basis, as shown in FIG. 7. The wavelength difference Δλ and the center wavelength λc calculated from the measured wavelengths λ_{S} and λ_{L} may therefore also change.

FIG. 8 is a timing chart showing an example of the relationship between the number of pulses of the excimer laser light output from the laser apparatus 100 and the current value of the current flowing through the semiconductor laser 132. In FIG. 8, the horizontal axis represents the number of pulses (or time), and the vertical axis represents the current value. The horizontal axis in FIG. 8 corresponds to the horizontal axis in FIG. 7, and FIG. 8 shows an example of the two-wavelength control in which the odd-numbered pulses are pulses of the excimer laser light having the shorter wavelength λ_{S}, and the even-numbered pulses are pulses of the excimer laser light having the longer wavelength λ_{L}. The laser apparatus 100 alternately changes the current value I of the current caused to flow through the semiconductor laser 132 to the current value I_{S} at the short wavelength and the current value I_{L} at the long wavelength, as shown in FIG. 8.

The thus configured wavelength control, in which the wavelengths are periodically changed to two wavelengths, is performed as follows, as described with reference to the flowchart in FIG. 6.

The laser apparatus 100 calculates the wavelength difference Δλ between the two latest pulses (corresponding to one wavelength change cycle) from the wavelengths λ_{S} and λ_{L} measured on a pulse basis, and feeds the calculated wavelength difference Δλ back to the difference ΔI between the current values of the current flowing through the semiconductor laser 132. That is, the laser control processor 12A corrects the current value difference ΔI based on the difference δΔλ between the target wavelength difference Δλt and the latest wavelength difference Δλ, and reflects the result of the correction in the control of the current value I_{S} during the next short wavelength oscillation and the current value I_{L} during the next long wavelength oscillation.

Furthermore, the laser apparatus 100 calculates the center wavelength λc of the two latest wavelengths from the wavelengths λ_{S} and λ_{L} measured on a pulse basis, and feeds the calculated center wavelength λc back to the average current value Ic of the current flowing through the semiconductor laser device 138. That is, the laser control processor 12A corrects the average current value Ic based on the difference δλc between the target center wavelength λct and the latest center wavelength λc, and reflects the result of the correction in the control of the current value I_{S} during the next short wavelength oscillation and the current value I_{L} during the next long wavelength oscillation.

The current value I_{S} during the short wavelength oscillation is an example of the “first current value” in the present disclosure, and the current value I_{L} during the long wavelength oscillation is an example of the “second current value” in the present disclosure. The laser control processor 12A is an example of the “processor” in the present disclosure.

### 4.1.3 Effects and Advantages

The laser apparatus 100 according to the first embodiment employs the configuration including the solid-state seeder 102 including the wavelength-variable semiconductor laser 132 and the excimer amplifier 112, and controls the current value I of the current caused to flow through the semiconductor laser 132 in such a way that the wavelength λ measured on a pulse basis alternately approaches the target short wavelength λ_{S}t and the target long wavelength λ_{L}t on a pulse basis. The thus configured laser apparatus 100 can perform highly accurate two-wavelength exposure even at a repetition frequency of 4 kHz or higher.

### 4.1.4 Others

In the first embodiment, the CW light output from the semiconductor laser 132 is converted into pulse laser light by causing a pulse current to pass through the SOA 136, but the pulse laser light is not necessarily generated as described above. For example, the CW light output from the semiconductor laser 132 may be amplified into pulse laser light by exciting the titanium sapphire crystal of the solid-state amplifier 106 with pulse excitation light.

The solid-state seeder 102 may include a system that includes a CW-oscillation semiconductor laser and a pulsing apparatus, and controls the current value of the current caused to flow through the semiconductor laser to change the wavelength. The solid-state seeder 102 may instead include a system using an optical shutter in place of the SOA 136 to perform the light pulsing. The optical shutter may, for example, be the combination of an electro-optical (EO) Pockels cell and polarizers.

The first embodiment shows a multipath amplifier as the excimer amplifier 112, but a multipath amplifier is not necessarily used, and the amplifier may, for example, be an amplifier with an optical resonator such as a Fabry-Perot resonator or a ring resonator.

The first embodiment has been described with reference to the case where the solid-state seeder 102 and the ArF excimer amplifier are employed, but not necessarily, and the combination of an excimer amplifier using a KrF laser gas and a solid-state seeder that operates at an oscillation wavelength in a wavelength region over which the KrF excimer is amplified may be employed. As a specific example, the solid-state seeder may have a configuration including a semiconductor laser system that outputs pulse laser light having a wavelength of about 745.2 nm, a solid-state amplifier, and a wavelength conversion system that converts the pulse laser light in terms of wavelength into third harmonic light having a wavelength of about 248.4 nm. Nonlinear crystals used in the wavelength conversion system in this case may be an LBO crystal that converts the pulse laser light in terms of wavelength into second harmonic light, and a CLBO crystal that performs sum frequency operation on the second harmonic light and the fundamental-wave light.

### 4.2 Example of Semiconductor Laser System

### 4.2.1 Configuration

FIG. 9 schematically shows the configuration of the semiconductor laser system 104. The semiconductor laser system 104 includes the distributed feedback (DFB) semiconductor laser 132 operating in the single longitudinal mode, a semiconductor laser control processor 134, and the SOA 136. The semiconductor laser 132 includes the semiconductor laser device 138, a Peltier device 148, a temperature sensor 150, a current controller 152, and a temperature controller 154. The semiconductor laser device 138 includes a first cladding layer 140, an active layer 142, and a second cladding layer 144 and further includes a grating 146 at the boundary between the active layer 142 and the second cladding layer 144. The semiconductor laser 132 is an example of the “first semiconductor laser” in the present disclosure.

The Peltier device 148 and the temperature sensor 150 are fixed to the semiconductor laser device 138. The semiconductor laser control processor 134 is provided with a signal line that receives data on the current value I and a set temperature Ts from the solid-state seeder control processor 110. The current controller 152 is provided with a signal line that receives data on the current value I from the semiconductor laser control processor 134. The temperature controller 154 is provided with a signal line that receives data on the set temperature Ts from the semiconductor laser control processor 134.

### 4.2.2 Operation

The oscillation center wavelength at which the semiconductor laser 132 operates can be changed by changing the set temperature Ts of the semiconductor laser device 138 and/or the current value I of the current flowing through the semiconductor laser device 138. The solid-state seeder control processor 110 acquires the set temperature Ts and the current value I from the laser control processor 12A, and transmits the acquired parameters to the semiconductor laser control processor 134. The semiconductor laser control processor 134 controls the temperature controller 154 and the current controller 152 in accordance with the set temperature Ts and the current value I, respectively.

To change the oscillation wavelength, at which the semiconductor laser 132 operates, at high speed, the current value I of the current flowing through the semiconductor laser device 138 is changed at high speed. The wavelength of the CW laser light can thus be changed at high speed.

The solid-state seeder control processor 110 acquires the trigger signal Tr2 from the laser control processor 12A. When the trigger signal Tr2 is input to the solid-state seeder 102, a pulse signal is input to the SOA 136.

Causing a pulse current according to the pulse signal to pass through the semiconductor that forms the SOA 136 pulses and amplifies the CW laser light output from the semiconductor laser 132, so that the pulse laser light PL1 is output. The CW laser light output from the semiconductor laser 132 and having the wavelength of about 773.6 nm is an example of the “first laser light” in the present disclosure. The SOA 136 is an example of the “first amplifier” in the present disclosure.

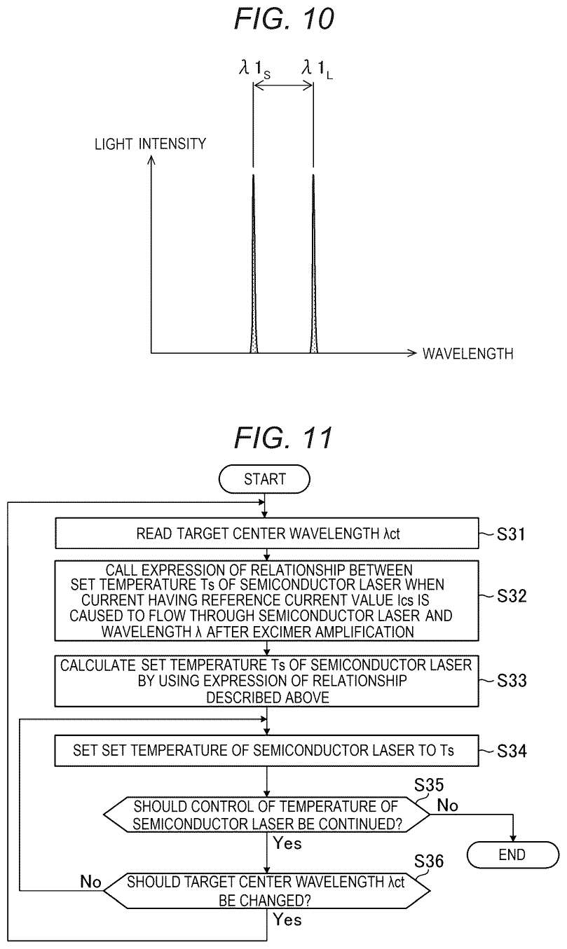

FIG. 10 is a graph showing an example of the two-wavelength spectrum of the pulse laser light PL1 output from the semiconductor laser system 104. Changing the current value I on a pulse basis allows the semiconductor laser system 104 to alternately output the pulse laser light PL1 having a wavelength λ1_{S} and the pulse laser light PL1 having a wavelength λ1_{L}, as shown in FIG. 10.

### 4.2.3 Others

The SOA 136 does not necessarily perform pulsing and amplification, and a DC current may, for example, be caused to flow through the SOA 136 to cause the SOA 136 to amplify the CW laser light. In this case, the downstream solid-state amplifier 106 is an amplifier that pulses and amplifies the CW laser light.

### 4.3 Example of Control of Temperature of Semiconductor Laser

### 4.3.1 First Example of Flowchart

FIG. 11 is a flowchart showing a first example of the control of the temperature of the semiconductor laser performed by the laser control processor 12A. FIG. 11 shows an example of controlling the temperature of the semiconductor laser 132 based on the target center wavelength λct.

In step S31, the laser control processor 12A reads data on the target center wavelength λct.

In step S32, the laser control processor 12A calls the expression of the relationship between the set temperature Ts of the semiconductor laser when a current having the reference current value Ics is caused to flow through the semiconductor laser 132, and the wavelength λ after the excimer amplification.

In step S33, the laser control processor 12A calculates the set temperature Ts of the semiconductor laser 132 which corresponds to the target center wavelength λct, by using the expression of the relationship described above.

In step S34, the laser control processor 12A sets the set temperature of the semiconductor laser 132 to Ts.

In step S35, the laser control processor 12A evaluates whether the control of the temperature of the semiconductor laser 132 should be continued. When the temperature control should not be continued (No in step S35), the laser control processor 12A terminates the flowchart in FIG. 11. When the temperature control should be continued (Yes in step S35), the laser control processor 12A proceeds to the process in step S36.

In step S36, the laser control processor 12A evaluates whether the target center wavelength λct should be changed. When the target center wavelength λct should not be changed (No in step S36), the laser control processor 12A returns to the process in step S34. When the target center wavelength λct should be changed (Yes in step S36), the laser control processor 12A returns to the process in step S31.

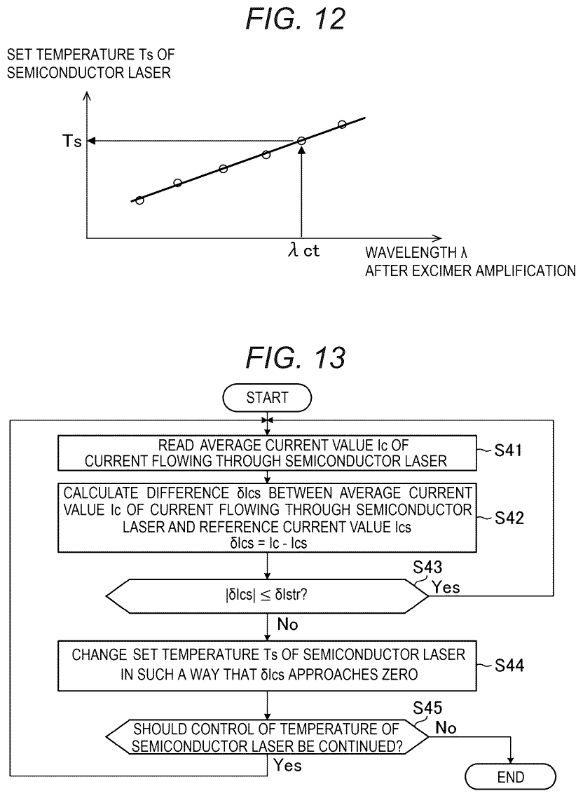

FIG. 12 is a graph showing an example of the relationship between the set temperature Ts of the semiconductor laser 132 when the current value is the reference current value Ics, and the wavelength λ after the excimer amplification. In FIG. 12, the horizontal axis represents the wavelength λ after the excimer amplification, and the vertical axis represents the set temperature Ts of the semiconductor laser 132. As the expression of the relation used in step S32 in FIG. 11, a relationship such as that shown in FIG. 12 may be actually measured in advance, and an approximate straight line or an approximate curve may be determined from the actually measured data. Still instead, table data may be used in place of the approximate straight line or the approximate curve as the expression of the relation.

### 4.3.2 Second Example of Flowchart

FIG. 13 is a flowchart showing a second example of the control of the temperature of the semiconductor laser 132 performed by the laser control processor 12A. FIG. 13 shows an example of controlling the temperature of the semiconductor laser 132 based on the average current value Ic.

In step S41, the laser control processor 12A reads the average current value Ic of the current flowing through the semiconductor laser 132.

In step S42, the laser control processor 12A calculates a difference δIcs between the average current value Ic and the reference current value Ics by using the expression below.

$$δ Ics = Ic - Ics$$

In step S43, the laser control processor 12A evaluates whether the absolute value of the difference δIcs is smaller than or equal to an acceptable value δIstr. That is, the laser control processor 12A evaluates whether |δIcs|≤δIstr is satisfied. When |δIcs|≤δIstr is satisfied (Yes in step S43), the laser control processor 12A returns to the process in step S41. When |δIcs|≤δIstr is not satisfied (No in step S43), the semiconductor laser control processor 134 proceeds to the process in step S44.

In step S44, the laser control processor 12A changes the set temperature Ts of the semiconductor laser 132 in such a way that the difference δIcs approaches zero.

In step S45, the laser control processor 12A evaluates whether the control of the temperature of the semiconductor laser 132 should be continued. When the temperature control should be continued (Yes in step S45), the laser control processor 12A returns to the process in step S41. When the temperature control should not be continued (No in step S45), the laser control processor 12A terminates the processes in the flowchart in FIG. 13.

### 4.3.3 Effects and Advantages

When the target center wavelength λct has been greatly changed, the wavelength λ after the excimer amplification cannot be controlled in some cases only by the current value I of the current flowing through the semiconductor laser 132. Setting the temperature of the semiconductor laser 132 as shown in FIG. 11 or 13 allows the average current value Ic of the current caused to flow through the semiconductor laser 132 to be maintained near the reference current value Ics even when the target center wavelength λct is greatly changed.

As a result, even when the target wavelength of the two-wavelength spectrum is greatly changed, the wavelength can be swung to each of the two wavelengths with high precision on a pulse basis.

### 4.4 Example of Wavelength Conversion System

### 4.4.1 Configuration

FIG. 14 schematically shows the configuration of the wavelength conversion system 108. The wavelength conversion system 108 includes a KBBF crystal 162, an LBO crystal 164, rotary stages 166 and 168 as actuators, and a rotary stage driver 170 as a controller that controls the actuators. The term “KBBF” is expressed by a chemical formula KBe₂BO₃F₂. The term “LBO” is expressed by a chemical formula LiB₃O₅. The KBBF crystal 162 is an example of the “first nonlinear crystal” in the present disclosure.

The KBBF crystal 162 is disposed on the rotary stage 166. The LBO crystal 164 is disposed on the rotary stage 168. To rotate the wavelength converters at high speed, the rotary stages 166 and 168 are each a rotary stage including a piezoelectric device. The rotary stage driver 170 controls the angle of each of the rotary stages 166 and 168.

The actuators may be heaters for controlling the temperatures of the nonlinear crystals, and the controller may be a temperature controller.

### 4.4.2 Operation

The pulse laser light PL1 having been input to the wavelength conversion system 108 enters the LBO crystal 164. The LBO crystal 164 converts the pulse laser light PL1 having the wavelength of about 773.6 nm into pulse laser light having a wavelength of about 386.8 nm, which is second harmonic light of the incident pulse laser light.

The KBBF crystal 162 converts the pulse laser light output from the LBO crystal 164 and having the wavelength of about 386.8 nm into pulse laser light PL2 having the wavelength of about 193.4 nm, which is second harmonic light of the incident pulse laser light.

The converted pulse laser light PL2 having the wavelength of about 193.4 nm is output from the wavelength conversion system 108.

In the case of one-wavelength oscillation, the laser control processor 12A controls the angle of incidence of the pulse laser light to be incident on each of the KBBF crystal 162 and the LBO crystal 164 in such a way that the wavelength conversion efficiency is maximized at the target wavelength λt, that is, phase matching is achieved. The angles of incidence of the pulse laser light to be incident on the KBBF crystal 162 and the LBO crystal 164 are controlled by rotation of the rotary stages 166 and 168.

FIG. 15 shows graphs schematically showing wavelength conversion efficiency curves for the KBBF crystal 162 and the LBO crystal 164. In FIG. 15, the horizontal axis represents the wavelength λ after the wavelength conversion, and the vertical axis represents wavelength conversion efficiency n. The wavelength conversion efficiency of the KBBF crystal 162, which is the downstream nonlinear crystal, decreases at wavelengths that deviate to some extent from the wavelength λ after the wavelength conversion, as shown in FIG. 15. Therefore, when the two-wavelength spectrum has a large target wavelength difference Δλt, the pulse energy of the pulse laser light converted in terms of wavelength may decrease unless the angle of incidence of the pulse laser light to be incident on the KBBF crystal 162 is controlled to achieve the phase matching on a pulse basis.

### 4.5 Nonlinear Crystal Temperature Adjustment System

### 4.5.1 Configuration

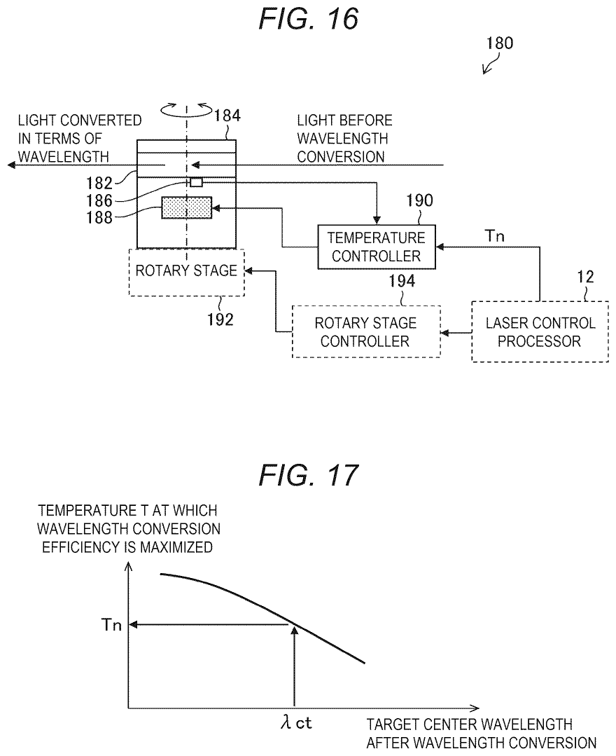

FIG. 16 schematically shows an example of the configuration of a nonlinear crystal temperature adjustment system 180. The temperature adjustment system 180 shown in FIG. 16 can be used to adjust the temperatures of the KBBF crystal 162 and the LBO crystal 164 in FIG. 14.

The nonlinear crystal temperature adjustment system 180 includes a nonlinear crystal 182, a nonlinear crystal holder 184, a temperature sensor 186, a heater 188, and a temperature controller 190.

The nonlinear crystal 182 is fixed to the nonlinear crystal holder 184. The temperature sensor 186 is disposed near the nonlinear crystal 182 in the nonlinear crystal holder 184. The heater 188 is disposed within the nonlinear crystal holder 184.

The nonlinear crystal temperature adjustment system 180 may further include a rotary stage 192, which controls the angle of incidence of the pulse laser light to be incident on the nonlinear crystal 182, and a rotary stage controller 194, which controls the rotary stage 192.

### 4.5.2 Operation

The temperature controller 190 receives data on a temperature Tn of the nonlinear crystal 182 from the laser control processor 12A. The temperature controller 190 controls the power applied to the heater 188 in such a way that the temperature of the nonlinear crystal 182 becomes the received temperature Tn to cause the temperature of the nonlinear crystal 182 to approach Tn.

The laser control processor 12A determines and sets the temperature Tn of the nonlinear crystal 182 from the target wavelength λt based on data on the relationship between the wavelength and temperature that maximizes the wavelength conversion efficiency of the nonlinear crystal 182. The data may be measured in advance, and an approximate straight line or an approximate curve may be determined based on the measured data and stored, or the measured data may be stored as table data.

When the phase matching cannot be achieved by the temperature control alone, the phase matching may be achieved by controlling the angle of incidence of the pulse laser light to be incident on the nonlinear crystal 182 with the rotary stage 192.

FIG. 17 shows the data on the relationship between the wavelength and temperature that maximizes the wavelength conversion efficiency of the nonlinear crystal 182, which is stored by the laser control processor 12A, and is a graph showing the relationship between the target center wavelength after the wavelength conversion and a temperature T, at which the wavelength conversion efficiency is maximized. In FIG. 17, the horizontal axis represents the target center wavelength after the wavelength conversion, and the vertical axis represents the temperature T, at which the wavelength conversion efficiency is maximized. The temperature at which the wavelength conversion efficiency is maximized is Tn when the target center wavelength after the wavelength conversion is λct, as shown in FIG. 17.

### 4.5.3 Others

When the nonlinear crystal 182 is a KBBF crystal or an LBO crystal, the nonlinear crystal 182 does not need to be disposed in a cell. On the other hand, when the nonlinear crystal 182 is a CLBO crystal, which is hygroscopic, it is necessary to dispose the nonlinear crystal 182 and the nonlinear crystal holder 184 in a cell that is not shown and control the temperature of the interior of the cell to fall within a range, for example, from 120 to 170° C. The term “CLBO” is expressed by a chemical formula CsLiB₆O₁₀.

### 4.6 Method for Controlling Wavelength Conversion System

### 4.6.1 Example of Flowchart

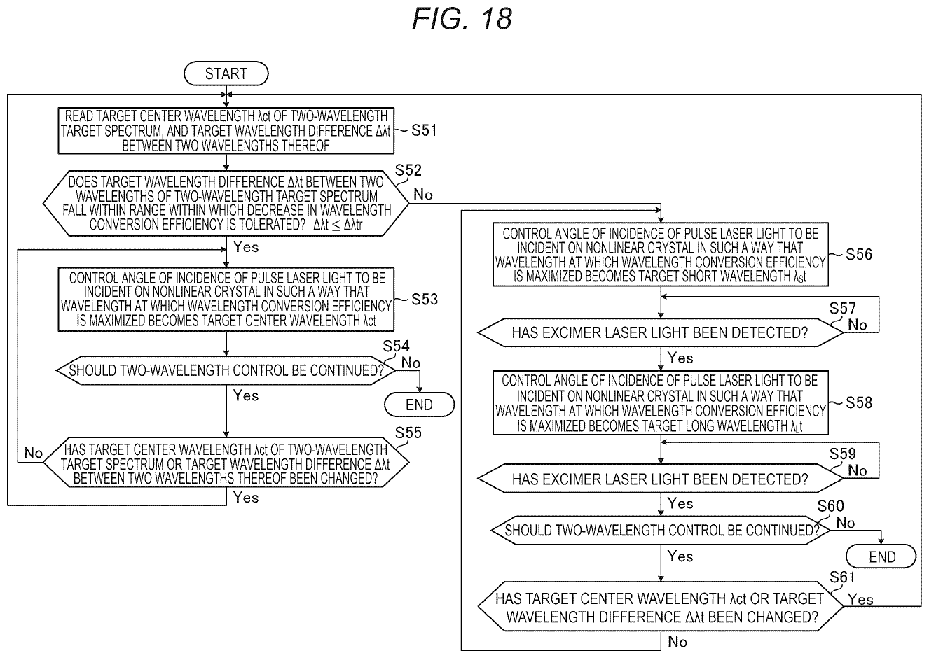

FIG. 18 is a flowchart showing an example of control of the wavelength conversion system 108 performed by the laser control processor.

In step S51, the laser control processor 12A reads values as a result of calculation of the target center wavelength λct of the two-wavelength spectrum and the target wavelength difference Δλt between the two wavelengths thereof based on the two-wavelength control parameter data received from the exposure control processor 310.

In step S52, the laser control processor 12A evaluates whether the target wavelength difference Δλt between the two wavelengths of the two-wavelength spectrum acquired in step S51 falls within a range Axtr, within which a decrease in wavelength conversion efficiency is tolerated. That is, the laser control processor 12A evaluates whether Δλt≤ Δλtr is satisfied. When Δλt≤Δλtr is satisfied (Yes in step S52), the laser control processor 12A proceeds to the process in step S53. When Δλt≤Δλtr is not satisfied (No in step S52), the laser control processor 12A proceeds to the process in step S56.

In step S53, the laser control processor 12A controls the angle of incidence of the pulse laser light to be incident on each of the KBBF crystal 162 and the LBO crystal 164 in such a way that the wavelength at which the wavelength conversion efficiency is maximized becomes the target center wavelength λct acquired in step S51.

In step S54, the laser control processor 12A evaluates whether the two-wavelength control should be continued. When the two-wavelength control should be continued (Yes in step S54), the laser control processor 12A proceeds to the process in step S55. When the two-wavelength control should not be continued (No in step S54), the laser control processor 12A terminates the processes in the flowchart in FIG. 18.

In step S55, the laser control processor 12A evaluates whether the target center wavelength λct of the two-wavelength spectrum or the target wavelength difference Δλt between the two wavelengths thereof has been changed. When the target center wavelength λct of the two-wavelength spectrum or the target wavelength difference Δλt between the two wavelengths thereof has not been changed (No in step S55), the laser control processor 12A returns to the process in step S53. When the target center wavelength λct of the two-wavelength spectrum or the target wavelength difference Δλt between the two wavelengths thereof has been changed (Yes in step S55), the laser control processor 12A returns to the process in step S51.

In step S56, the laser control processor 12A controls the angle of incidence of the pulse laser light to be incident on each of the KBBF crystal 162 and the LBO crystal 164 in such a way that the wavelength at which the wavelength conversion efficiency is maximized becomes the target short wavelength λ_{S}t.

In step S57, the laser control processor 12A evaluates whether the excimer laser light has been detected by the spectrum monitor 126. When the excimer laser light has not been detected (No in step S57), the laser control processor 12A waits until the excimer laser light is detected. When the excimer laser light has been detected (Yes in step S57), the laser control processor 12A proceeds to the process in step S58.

In step S58, the laser control processor 12A controls the angle of incidence of the pulse laser light to be incident on each of the KBBF crystal 162 and the LBO crystal 164 in such a way that the wavelength at which the wavelength conversion efficiency is maximized becomes the target long wavelength λ_{L}t.

In step S59, the laser control processor 12A evaluates whether the excimer laser light has been detected by the spectrum monitor 126. When the excimer laser light has not been detected (No in step S59), the laser control processor 12A waits until the excimer laser light is detected. When the excimer laser light has been detected (Yes in step S59), the laser control processor 12A proceeds to the process in step S60.

In step S60, the laser control processor 12A evaluates whether the two-wavelength control should be continued. When the two-wavelength control should be continued (Yes in step S60), the laser control processor 12A proceeds to the process in step S61. When the two-wavelength control should not be continued (No in step S60), the laser control processor 12A terminates the processes in the flowchart in FIG. 18.

In step S61, the laser control processor 12A evaluates whether the target center wavelength λct of the two-wavelength spectrum or the target wavelength difference Δλt between the two wavelengths thereof has been changed. When the target center wavelength λct of the two-wavelength spectrum or the target wavelength difference Δλt between the two wavelengths thereof has not been changed (No in step S61), the laser control processor 12A returns to the process in step S56. When the target center wavelength λct of the two-wavelength spectrum or the target wavelength difference Δλt between the two wavelengths thereof has been changed (Yes in step S61), the laser control processor 12A returns to the process in step S51.

### 4.6.2 Operation

The laser control processor 12A evaluates whether a decrease in wavelength conversion efficiency caused by the target wavelength difference Δλt between the two wavelengths of the two-wavelength spectrum falls within a tolerable range (step S52), as shown in FIG. 18. The target wavelength difference Δλt should fall, for example, within a range from 1 pm to 2 pm. Based on the result of the evaluation, the laser control processor 12A controls differently the angle of incidence of the pulse laser light to be incident on the KBBF crystal 162 and the LBO crystal 164, which are the wavelength converters.

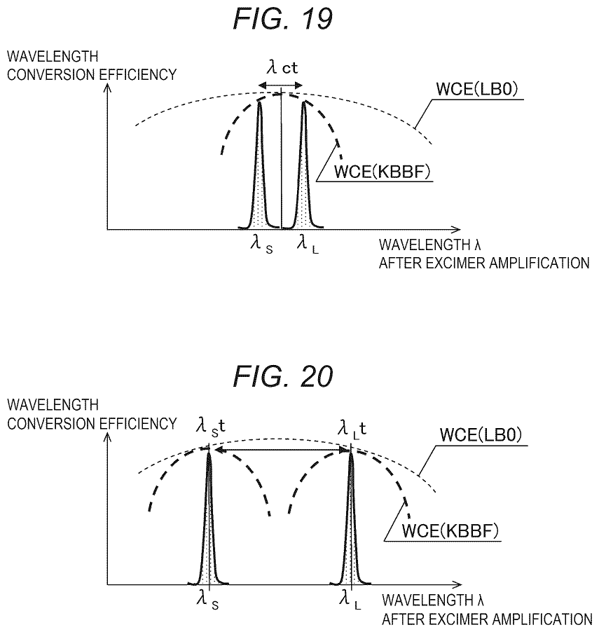

FIGS. 19 and 20 are graphs showing the relationship between the wavelength A after the excimer amplification and the wavelength conversion efficiency. In FIGS. 19 and 20, the horizontal axis represents the wavelength λ after the excimer amplification, and the vertical axis represents the wavelength conversion efficiency. “WCE (LBO)” in FIGS. 19 and 20 indicates wavelength conversion efficiency curves for the LBO crystal 164, and “WCE (KBBF)” indicates wavelength conversion efficiency curves for the KBBF crystal 162.

When the target wavelength difference Δλt between the two wavelengths of the two-wavelength spectrum falls within the range within which a decrease in wavelength conversion efficiency is suppressed, the laser control processor 12A controls the angle of incidence of the pulse laser light to be incident on each of the KBBF crystal 162 and the LBO crystal 164 in such a way that the highest wavelength conversion efficiency is achieved at the target center wavelength λct of the two-wavelength spectrum (step S53 in FIG. 18), as shown in FIG. 19.

On the other hand, when the target wavelength difference Δλt between the two wavelengths of the two-wavelength spectrum is greater than the range within which a decrease in wavelength conversion efficiency is suppressed, the laser control processor 12A at least controls the angle of incidence of the pulse laser light to be incident on the KBBF crystal 162, which is the nonlinear crystal disposed at the most downstream position in the wavelength conversion system 108, in such a way that the conversion efficiency is maximized at each of the target short wavelength λ_{S}t and the target long wavelength λ_{L}t on a pulse basis synchronously with each pulse (steps S56 and S58 in FIG. 18), as shown in FIG. 20.

When the target wavelength difference Δλt between the two wavelengths of the two-wavelength spectrum is even greater, the angle of incidence of the pulse laser light to be incident on the LBO crystal 164, which is the second nonlinear crystal next to the most downstream nonlinear crystal, may also be so controlled that the conversion efficiency is maximized at each of the target short wavelength λ_{S}t and the target long wavelength λ_{L}t.

### 4.6.3 Effects and Advantages

When the target wavelength difference Δλt falls within the tolerable range, changes in wavelength conversion efficiency are suppressed, so that the pulse energy and the wavelengths λ_{S} and λ_{L} of the two-wavelength spectrum are controlled with high precision on a pulse basis, as described with reference to FIG. 18.

When the target wavelength difference Δλt≤1 to 2 pm is satisfied, increasing the depth of focus allows a margin for formation and processing of a contact-hole photoresist pattern to be provided.

When the target wavelength difference Δλt≥1 to 2 pm is satisfied, the two-wavelength exposure can also be used to form a thick photoresist film in a 3D semiconductor manufacturing process.

### 5. Second Embodiment

### 5.1 Configuration

The configuration in a second embodiment may be the same as that in the first embodiment.

### 5.2 Operation

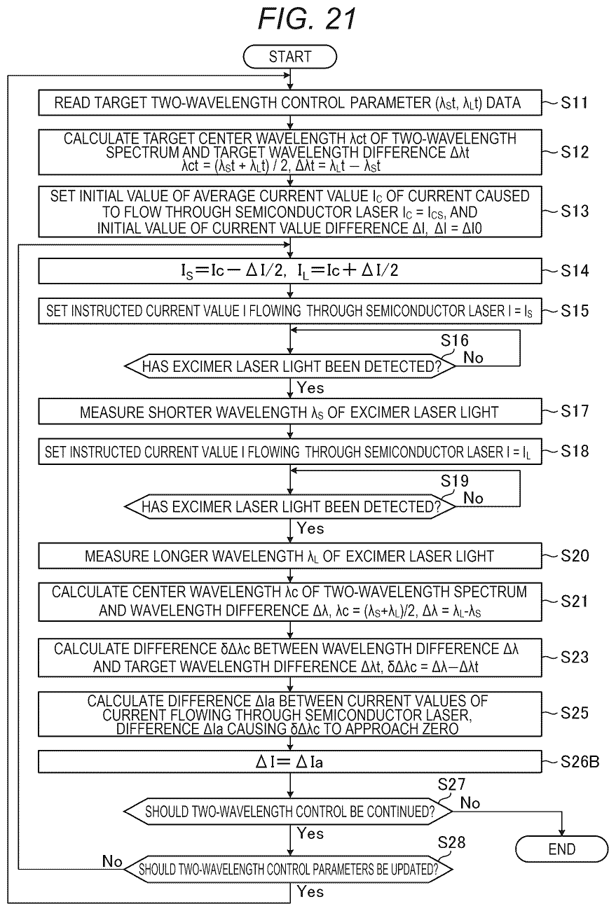

FIG. 21 is a flowchart showing an example of processes carried out by the laser control processor 12A in the second embodiment. Differences between FIGS. 21 and 6 will be described.

In FIG. 6, after the average current value Ic is set in step S13 at the reference current value Ics, which is an initial value, the average current value Ica is so calculated that the difference δλc between the center wavelength λc and the target center wavelength of the two-wavelength spectrum approaches zero, and the value of the average current value Ic is dynamically updated (steps S22, S25, and S26). In FIG. 21, however, the average current value Ic is set at the reference current value Ics in step S13, and the value of the average current value Ic is then fixed to the reference current value Ics.

That is, in FIG. 21, steps S22 and S24 are deleted, and step S26 is replaced with step S26B.

In step S26B, the laser control processor 12A updates the current value difference ΔI by replacing the value of the current value difference ΔI with ΔIa.

The other steps may be the same as those in FIG. 6.

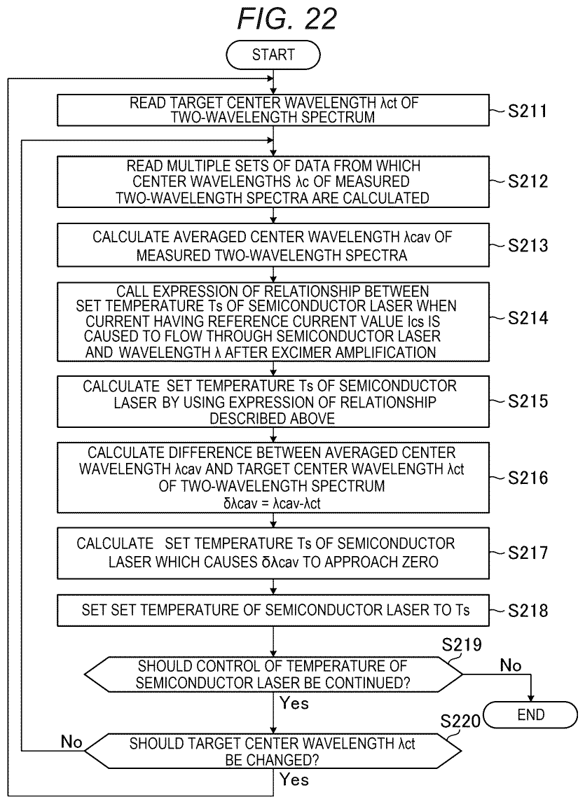

FIG. 22 is a flowchart showing an example of the control of the temperature of the semiconductor laser 132 performed by the laser control processor 12A in the second embodiment. FIG. 22 shows an example in which the center wavelength λc of the two-wavelength spectrum is fed back to the set temperature Ts of the semiconductor laser 132.

In step S211, the laser control processor 12A reads the target center wavelength λct of the two-wavelength spectrum.

In step S212, the laser control processor 12A measures the center wavelength λc of the two-wavelength spectrum on a one-cycle basis, and reads multiple sets of data containing a predetermined number of samples from which the center wavelength λc has been calculated.

In step S213, the laser control processor 12A calculates an average center wavelength λcav of the measured two-wavelength spectra. That is, the laser control processor 12A uses data on the center wavelengths λc, which are read in step S212 and include the predetermined number of samples, to calculate the average (center wavelength λcav) of the center wavelengths λc.

The processes in steps S214 and S215 are the same as those in steps S32 and S33 in FIG. 11, respectively.

In step S216, the laser control processor 12A calculates a difference δλcav between the average center wavelength λcav and the target center wavelength λct of the two-wavelength spectrum by using the expression below.

$$6 λ cav = λ cav - λ ct$$

In step S217, the laser control processor 12A calculates the set temperature Ts of the semiconductor laser 132 which causes the difference δλcav to approach zero. The laser control processor 12A determines the set temperature Ts based on the relationship described in FIG. 12.

Thereafter, in step S218, the laser control processor 12A sets the set temperature of the semiconductor laser to Ts.

In step S219, the laser control processor 12A evaluates whether the control of the temperature of the semiconductor laser 132 should be continued. When the temperature control should be continued (Yes in step S219), the laser control processor 12A proceeds to the process in step S220. When the temperature control should not be continued (No in step S219), the laser control processor 12A terminates the processes in the flowchart in FIG. 22.

In step S220, the laser control processor 12A evaluates whether the target center wavelength λct should be changed. When the target center wavelength λct should not be changed (No in step S220), the laser control processor 12A returns to the process in step S212. When the target center wavelength λct should be changed (Yes in step S220), the laser control processor 12A returns to the process in step S211.

It is difficult to control the temperature of the semiconductor laser 132 at high speed on a pulse basis. It is therefore preferable that the center wavelengths λc of the measured two-wavelength spectra are averaged over the predetermined number of samples, and that the average center wavelengths λc is fed back to the set temperature Ts of the semiconductor laser 132 in such a way that the average approaches the target center wavelength λct, as shown in the flowchart of FIG. 22.

### 5.3 Effects and Advantages

The second embodiment can provide the same effects as the first embodiment.

### 5.4 Others

The average of the center wavelengths λc of the measured two-wavelength spectra is not limited to an arithmetic average, and may instead be a moving average.

### 6. Third Embodiment

### 6.1 Configuration

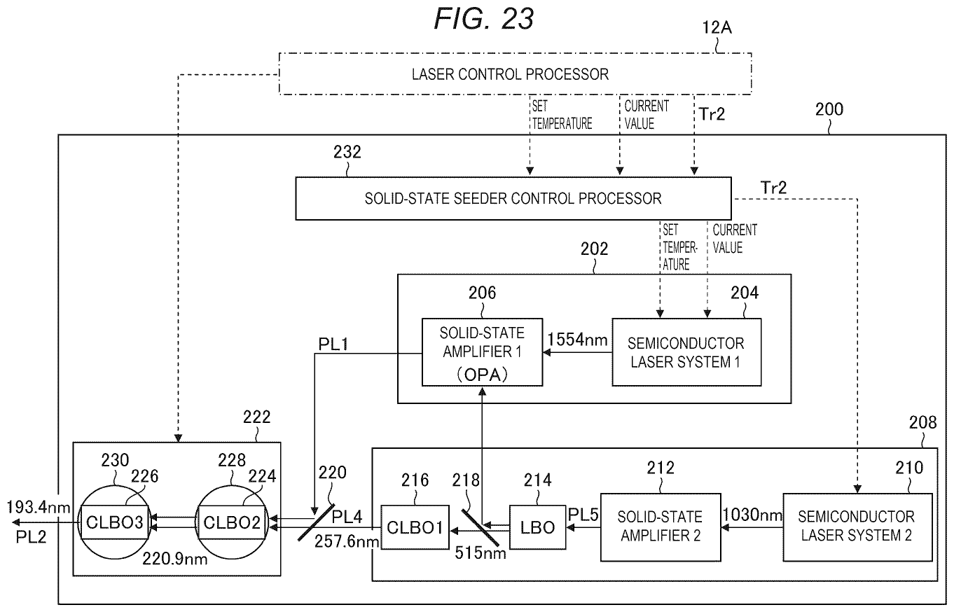

In a third embodiment, a variation of the solid-state seeder 102 will be described. The solid-state seeder 102 shown in FIG. 5 can be replaced with a solid-state seeder 200 shown in FIG. 23. The solid-state seeder 200 includes a first solid-state laser apparatus 202, a second solid-state laser apparatus 208, a dichroic mirror 220, a wavelength conversion system 222, and a solid-state seeder control processor 232.

The solid-state seeder 200 has a system configuration in which the wavelength conversion system 222 performs a double sum frequency operation to convert pulse laser light PL1 output from the first solid-state laser apparatus 202 and having a wavelength of about 1554 nm and pulse laser light PL4 output from the second solid-state laser apparatus 208 and having a wavelength of about 257.6 nm into pulse laser light PL2 having the wavelength of about 193.4 nm.

The first solid-state laser apparatus 202 includes a first semiconductor laser system 204 and a first solid-state amplifier 206. In FIG. 23, regarding notations with numerals, for example, the “semiconductor laser system 1” and the “solid-state amplifier 1” represent the first semiconductor laser system and the first solid-state amplifier.

The first semiconductor laser system 204 can be configured in the same manner as the semiconductor laser system 104 shown in FIG. 10, but operates at an oscillation wavelength different from that at which the semiconductor laser system 104 operates. The first semiconductor laser system 204 includes the semiconductor laser 132 that performs CW oscillation in the single longitudinal mode at the wavelength of about 1554 nm, and the SOA 136. In the description, the semiconductor laser 132 and the SOA 136 used in the first semiconductor laser system 204 are called a first semiconductor laser and a first SOA.

The first solid-state amplifier 206 is an optical parametric amplifier (OPA). The OPA is made, for example, of periodically poled lithium niobate (PPLN) or periodically poled KTP or potassium titanyl phosphate crystal (PPKTP).

The first solid-state amplifier 206 has a configuration that receives pulse laser light that will be described later, has a wavelength of 1030 nm, and serves as pumping light and laser light output from the first semiconductor laser system 204 as seed light, and pulses and amplifies the seed light.

The second solid-state laser apparatus 208 includes a second semiconductor laser system 210, a second solid-state amplifier 212, an LBO crystal 214 and a first CLBO crystal 216, which are two nonlinear crystals that convert the light incident thereon in term of wavelength into fourth harmonic light, and a dichroic mirror 218. The fourth harmonic light output from the first CLBO crystal 216 is an example of the “second harmonic light” in the present disclosure. The LBO crystal 214 and the first CLBO crystal 216 are an example of the “second nonlinear crystal” in the present disclosure.

The second semiconductor laser system 210 can be configured in the same manner as the semiconductor laser system 104 shown in FIG. 10, but operates at an oscillation wavelength different from that at which the semiconductor laser system 104 operates. The second semiconductor laser system 210 includes the semiconductor laser 132 that performs CW oscillation in the single longitudinal mode at the wavelength of about 1030 nm, and the SOA 136. In the description, the semiconductor laser 132 and the SOA 136 used in the second semiconductor laser system 210 are called a second semiconductor laser and a second SOA. The continuous-wave laser light output from the second semiconductor laser and having the wavelength of about 1030 nm is an example of the “second laser light” in the present disclosure. The second SOA is an example of the “second amplifier” in the present disclosure.

The second solid-state amplifier 212 includes, for example, a Yb fiber amplifier or a Yb: YAG crystal.

The dichroic mirror 218 is disposed in the optical path between the LBO crystal 214 and the first CLBO crystal 216, transmits pulse laser light having a wavelength of about 515 nm at high transmittance, and reflects pulse laser light having the wavelength of about 1030 nm at high reflectance. The dichroic mirror 218 is so disposed that the pulse laser light reflected at high reflectance and having the wavelength of about 1030 nm enters the first solid-state amplifier 206 as pumping light for the first solid-state amplifier 206.

The wavelength conversion system 222 includes a second CLBO crystal 224, a third CLBO crystal 226, and rotary stages 228 and 230. The second CLBO crystal 224 and the third CLBO crystal 226 are disposed on the rotary stages 228 and 230, respectively, which each include a piezoelectric device and are each configured to be capable of changing the angle of incidence of the pulse laser light to be incident on the crystal at high speed.

The dichroic mirror 220 is configured to reflect the pulse laser light having the wavelength of about 1554 nm and output from the first solid-state laser apparatus 202 at high reflectance and transmit the pulse laser light having the wavelength of about 257.6 nm and output from the second solid-state laser apparatus 208 at high transmittance, and is so disposed that the two kinds of pulse laser light coaxially enter the wavelength conversion system 222.

### 6.2 Operation

In the solid-state seeder 200, the wavelength of pulse laser light PL2 output from the wavelength conversion system 222 is changed by changing the wavelength of the pulse laser light PL1 output from the first solid-state laser apparatus 202 on a pulse basis with the wavelength of the pulse laser light PL4 output from the second solid-state laser apparatus 208 fixed.

The second solid-state laser apparatus 208 operates as described below. The laser control processor 12A fixes the oscillation wavelength at which the second solid-state laser apparatus 208 operates to 1030 nm. That is, the laser control processor 12A causes the second semiconductor laser in the second semiconductor laser system 210 to undergo continuous laser oscillation with the current value of the current flowing through the second semiconductor laser fixed to cause the second semiconductor laser to output CW laser light.

Furthermore, the laser control processor 12A causes the second SOA and the second solid-state amplifier 212 to pulse and amplify the CW laser light in response to the trigger signal Tr2. The second solid-state amplifier 212 outputs pulse laser light PL5 having the wavelength of 1030 nm. The pulse laser light PL5 is an example of the “fifth pulse laser light” in the present disclosure.

The pulse laser light PL5 output from the second solid-state amplifier 212 and having the wavelength of 1030 nm is converted by the LBO crystal 214 into second harmonic light having a wavelength of 515 nm. The second harmonic light having the wavelength of 515 nm passes through the dichroic mirror 218 at high transmittance, and is converted by the first CLBO crystal 216 into the pulse laser light PL4 having the wavelength of 257.6 nm. The second solid-state laser apparatus 208 is an example of the “solid-state laser apparatus” in the present disclosure. The pulse laser light PL4 is an example of the “fourth pulse laser light” in the present disclosure.

The dichroic mirror 218 reflects at high reflectance the pulse laser light having the wavelength of 1030 nm that the LBO crystal 214 could not convert into the second harmonic light, and causes the reflected pulse laser light to enter the first solid-state amplifier 206 of the first solid-state laser apparatus 202 as pumping light therefor.

On the other hand, the laser control processor 12A controls the current value of the current flowing through the first semiconductor laser in the first semiconductor laser system 204 to alternately change on a pulse basis the wavelength of the pulse laser light PL1 output from the first solid-state laser apparatus 202 to two wavelengths in the vicinity of 1554 nm.

The pulse laser light PL1 having the wavelength of about 1554 nm and output from the first solid-state laser apparatus 202 and the pulse laser light PL4 having the wavelength of 257.6 nm and output from the first CLBO crystal are summed in terms of frequency and converted in terms of wavelength by the second CLBO crystal 224 into pulse laser light having a wavelength of about 220.9 nm. Furthermore, the pulse laser light having the wavelength of about 220.9 nm and the pulse laser light having the wavelength of 1554 nm are summed in terms of frequency and converted in terms of wavelength by the third CLBO crystal 226 into the pulse laser light PL2 having the wavelength of about 193.4 nm. The pulse laser light PL2 having a wavelength that alternately changes to λ_{S} and λ_{L} on a pulse basis is then output.

The laser control processor 12A alternately controls the wavelength of the pulse laser light on a pulse basis in such a way that the wavelength approaches λ_{S}t and λ_{L}t, which are wavelengths of the target two-wavelength spectrum, by performing the control in the flowchart shown in FIG. 6.

### 6.3 Others

In the system using the solid-state seeder 200, performing the control shown in the flowchart (FIG. 21) described in the second embodiment allows the wavelength of the pulse laser light to be so controlled on a pulse basis that the wavelength of the pulse laser light PL2 approaches each of the two target wavelengths.

### 7. Fourth Embodiment

### 7.1 Configuration

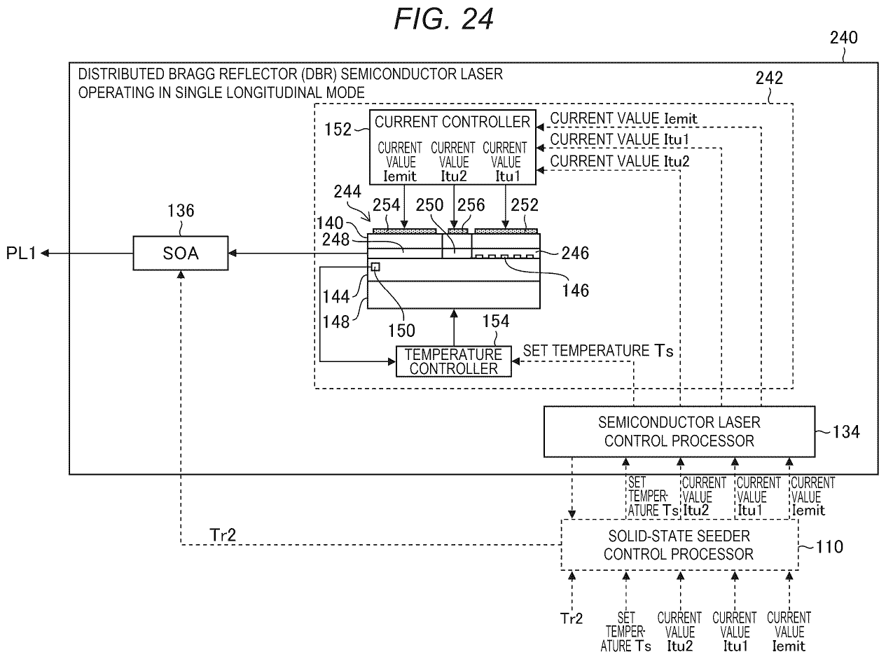

FIG. 24 schematically shows an example of the configuration of a distributed Bragg reflector (DBR) semiconductor laser system 240. The semiconductor laser system 240 can be used as the semiconductor laser system 104 in FIG. 5, the first semiconductor laser system 204 in FIG. 23, or the second semiconductor laser system 210 in FIG. 23.

The semiconductor laser system 240 includes a distributed Bragg reflector (DBR) semiconductor laser 242 operating in the single longitudinal mode in place of the semiconductor laser 132 in FIG. 9. The semiconductor laser 242 includes a semiconductor laser device 244.

The semiconductor laser device 244 includes, between the first cladding layer 140 and the second cladding layer 144, a feedback layer 246, an active layer 248, and a phase adjustment region 250. The feedback layer 246 includes the grating 146 at the boundary between the feedback layer 246 and the second cladding layer 144. The phase adjustment region 250 is disposed between the feedback layer 246 and the active layer 248.

In the semiconductor laser device 244, electrodes 252, 254, and 256 are disposed at the first cladding layer 140. The electrodes 252, 254, and 256 are provided in correspondence with the feedback layer 246, the active layer 248, and the phase adjustment region 250, respectively.

The other configurations are the same as those in FIG. 9. Note, however, that the current controller 152 is connected to the electrodes 252, 254, and 256 via wires, and is configured to be capable of independently controlling the values of the currents flowing through the wires.

### 7.2 Operation

The oscillation center wavelength at which the semiconductor laser 242 operates can be changed by changing the set temperature Ts of the semiconductor laser device 244 and/or a current value Itu1 or Itu2 of the current flowing through the semiconductor laser device 244. The solid-state seeder control processor 110 acquires the set temperature Ts, the current values Itu1 and Itu2, and a current value Iemit from the laser control processor 12A, and transmits the acquired parameters to the semiconductor laser control processor 134. The semiconductor laser control processor 134 controls the temperature controller 154 in accordance with the set temperature Ts, and controls the current controller 152 in accordance with the current values Itu1, Itu2, and Iemit.

When the oscillation wavelength at which the semiconductor laser 242 operates is changed at high speed over a fine adjustment range, the wavelength of the CW laser light can be changed at high speed by changing the current value Itu2 of the current flowing through the phase adjustment region 250 at high speed.

When the oscillation wavelength at which the semiconductor laser 242 operates is changed at high speed over a wide range, the wavelength of the CW laser light can be changed at high speed by changing the current value Itu1 of the current flowing through the grating 146 at high speed. Note, however, that the current value Itu2 of the current flowing to the phase adjustment region 250 may also be changed because the semiconductor laser 242 cannot operate at some oscillation wavelengths.

To cause the semiconductor laser 242 to operate at an oscillation wavelength and produce desired power, the current value Iemit of the current flowing through the active layer 248 is input to the semiconductor laser 242.

The solid-state seeder control processor 110 acquires the trigger signal Tr2 from the laser control processor 12A.

When the trigger signal Tr2 is input to the solid-state seeder 102 or 200, a pulse signal is input to the SOA 136.

Causing a pulse current according to the pulse signal to flow through the semiconductor that forms the SOA 136 pulses and amplifies the CW laser light output from the semiconductor laser device 244, so that the pulse laser light PL1 is output.

### 7.3 Others

The SOA 136 may receive a DC current flowing therethrough to amplify the CW laser light. In this case, the downstream solid-state amplifier 106, first solid-state amplifier 206, or second solid-state amplifier 212 is an amplifier that pulses and amplifies the CW laser light.

### 7.4 Effects and Advantages

In the distributed feedback semiconductor laser 132 described in FIG. 9, the current value I is a common parameter that changes the wavelength and adjusts the output power, so that changing the wavelength also changes the output power. In contrast, the distributed Bragg reflector semiconductor laser 242 is characterized in that the output power thereof changes only by a small amount even when the current value Itu1 or Itu2 is changed, because the parameter that primarily determines the output power is the current value Iemit of the current flowing through the active layer 248.

Since the change in wavelength of the light from the semiconductor lasers 242 and 132 is caused by a change in the refractive index according to a change in the carrier density in the laser waveguide, the carrier density is substantially fixed to a laser-oscillation threshold carrier density in the distributed feedback semiconductor laser 132 when a current greater than or equal to a laser oscillation threshold flows through the semiconductor laser 132. Therefore, when a current greater than or equal to the laser oscillation threshold flows through the semiconductor laser 132, the amount of change in wavelength is relatively small even when the injection current is increased or decreased.

In contrast, in the distributed Bragg reflector semiconductor laser 242, the carrier density in the active layer 248 is substantially fixed to the laser-oscillation threshold carrier density when a current greater than or equal to the laser oscillation threshold flows through the semiconductor laser 242, as in the semiconductor laser 132, but the portion including the grating 146 does not have any laser gain, and neither does the phase adjustment region 250, so that the carrier density can greatly change depending on the current injected to the semiconductor laser 242. The distributed Bragg reflector semiconductor laser 242 can therefore change the wavelength of the light therefrom by a greater amount than the distributed feedback semiconductor laser 132.

### 8. Fifth Embodiment

### 8.1 Configuration

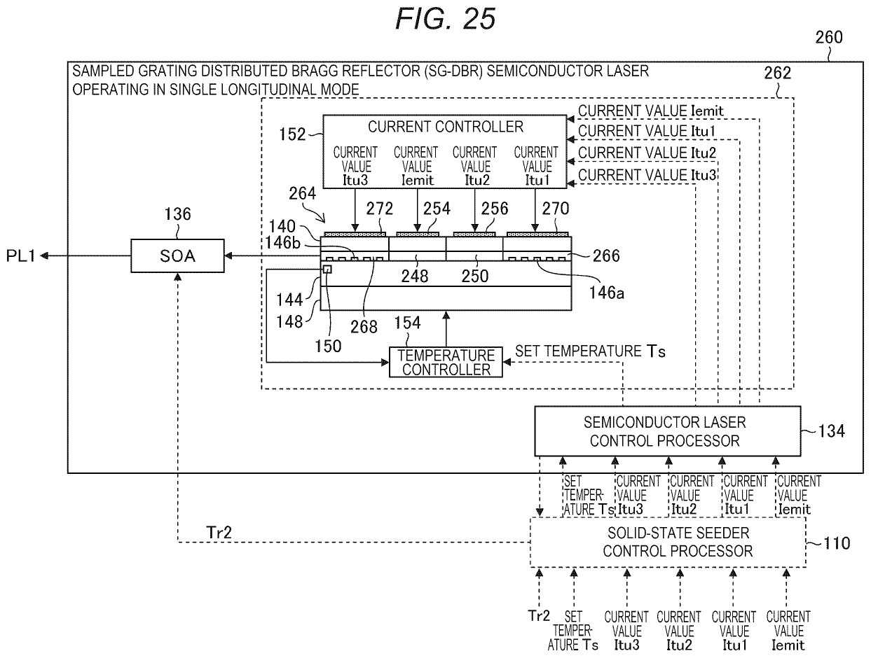

FIG. 25 schematically shows an example of the configuration of a sampled grating distributed Bragg reflector (SG-DBR) semiconductor laser system 260. The semiconductor laser system 260 can be used as the semiconductor laser system 104 in FIG. 5, the first semiconductor laser system 204 in FIG. 23, or the second semiconductor laser system 210 in FIG. 23.

The semiconductor laser system 260 includes a sampled grating distributed Bragg reflector (SG-DBR) semiconductor laser 262 operating in the single longitudinal mode in place of the semiconductor laser 132 in FIG. 9. The semiconductor laser 262 includes a semiconductor laser device 264.

The semiconductor laser device 264 includes the active layer 248, the phase adjustment region 250, a first feedback layer 266, and a second feedback layer 268 between the first cladding layer 140 and the second cladding layer 144.

The first feedback layer 266 includes a first grating 146a at the boundary between the first feedback layer 266 and the second cladding layer 144. The second feedback layer 268 includes a second grating 146b at the boundary between the second feedback layer 268 and the second cladding layer 144. The active layer 248 and the phase adjustment region 250 are disposed between the first feedback layer 266 and the second feedback layer 268.

In the semiconductor laser device 264, electrodes 254, 256, 270, and 272 are disposed at the first cladding layer 140. The electrodes 254, 256, 270, and 272 are provided in correspondence with the active layer 248, the phase adjustment region 250, the first feedback layer 266, and the second feedback layer 268, respectively.

The other configurations are the same as those in FIG. 9. Note, however, that the current controller 152 is connected to the electrodes 254, 256, 270, and 272 via wires, and is configured to be capable of independently controlling the values of the currents flowing through the wires.

### 8.2 Operation

The oscillation center wavelength at which the semiconductor laser 262 operates can be changed by changing the set temperature Ts of the semiconductor laser device 264 and/or at least one of current values Itu1, Itu2, and Itu3 of the current flowing through the semiconductor laser device 264. The solid-state seeder control processor 110 acquires the set temperature Ts, the current values Itu1, Itu2, Itu3, and Iemit from the laser control processor 12A, and transmits the acquired parameters to the semiconductor laser control processor 134. The semiconductor laser control processor 134 controls the current controller 152 in accordance with the current values Itu1, Itu2, Itu3, and Iemit.

When the oscillation wavelength at which the semiconductor laser 262 operates is changed at high speed over a fine adjustment range, the wavelength of the CW laser light can be changed at high speed by changing the current value Itu2 of the current flowing through the phase adjustment region 250 at high speed.

When the oscillation wavelength at which the semiconductor laser 262 operates is changed at high speed over a wide range, the wavelength of the CW laser light can be changed at high speed by changing the current value Itu1 of the current flowing through the first grating 146a and the current value Itu3 of the current flowing through the second grating 146b at high speed. Note, however, that the current value Itu2 of the current flowing to the phase adjustment region 250 may also be changed because the semiconductor laser 262 cannot operate at some oscillation wavelengths.

To cause the semiconductor laser 262 to operate at an oscillation wavelength and produce desired power, the current value Iemit of the current flowing through the active layer 248 is input to the semiconductor laser 262.

The laser control processor 12A instructs the solid-state seeder control processor 110 or 232 to set the current values Iemit, Itu1, and Itu2, and the set temperature Ts.

When the trigger signal Tr2 is input to the solid-state seeder 102 or 200, a pulse signal is input to the SOA 136.

Causing a pulse current according to the pulse signal to flow through the semiconductor that forms the SOA 136 pulses and amplifies the CW laser light output from the semiconductor laser device 264, so that pulse laser light is output.

### 8.3 Effects and Advantages

The SG-DBR semiconductor laser 262 is characterized in that the output power thereof changes only by a small amount even when the current value Itu1, itu2, or Itu3 is changed, because the parameter that primarily determines the output power is the current value Iemit of the current flowing through the active layer.

The semiconductor laser 262 has a configuration in which the corrugation period of the first grating 146a slightly differs from that of the second grating 146b, so that the wavelength changeable range of the semiconductor laser 262 is extremely wider than that of the distributed Bragg reflector semiconductor laser 242, that is, the wavelength can be changed over a range of 100 nm or wider.

### 9. Method for Manufacturing Electronic Devices

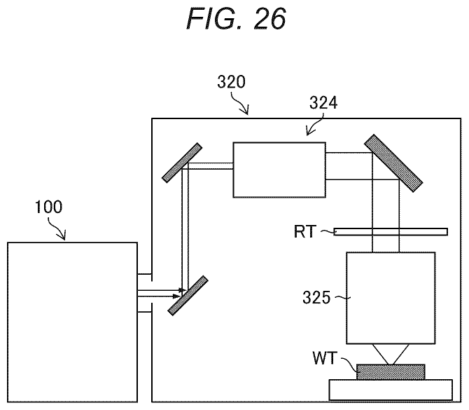

FIG. 26 schematically shows an example of the configuration of the exposure apparatus 300. The exposure apparatus 300 includes the illumination optical system 306 and the projection optical system 308. The illumination optical system 306 illuminates a reticle pattern of a reticle at the reticle stage RT with the laser light having entered the illumination optical system 306 from the laser apparatus 100. The projection optical system 308 performs reduction projection on the laser light having passed through the reticle R to bring the laser light into focus on a workpiece that is not shown but is placed on a workpiece table WT. The workpiece is a photosensitive substrate onto which a photoresist has been applied, such as a semiconductor wafer.

The exposure apparatus 300 synchronously moves the reticle stage RT and the workpiece table WT in parallel in directions opposite to each other to expose the workpiece to the laser light having reflected the reticle pattern. Semiconductor devices can be manufactured by transferring the reticle pattern onto the semiconductor wafer in the exposure step described above and then carrying out multiple other steps. The semiconductor devices are an example of the “electronic devices” in the present disclosure.

### 10. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of any thereof and any other than A, B, and C.

What is claimed is:

1. A laser apparatus comprising:
a first wavelength variable semiconductor laser configured to output first continuous-wave laser light;
a first amplifier configured to pulse and amplify the first laser light and output first pulse laser light;
a wavelength conversion system configured to convert a wavelength of the first pulse laser light and output resultant second pulse laser light;
an excimer amplifier configured to amplify the second pulse laser light and output resultant third pulse laser light;
a monitor module configured to measure a wavelength of the third pulse laser light; and
a processor configured to change a target wavelength of the third pulse laser light alternately to a first target wavelength and a second target wavelength longer than the first target wavelength,
calculate a center wavelength that is an average of a measured value of the wavelength of the third pulse laser light output at the first target wavelength and a measured value of the wavelength of the third pulse laser light output at the second target wavelength and a wavelength difference that is a difference between the measured values,
calculate an average current value that is an average of a first current value of a current flowing through the first semiconductor laser operating at the first target wavelength and a second current value of the current flowing through the first semiconductor laser operating at the second target wavelength in such a way that a difference between the center wavelength and a target center wavelength that is an average of the first target wavelength and the second target wavelength decreases,
calculate a current value difference that is a difference between the first current value and the second current value in such a way that the wavelength difference and a target wavelength difference that is a difference between the first target wavelength and the second target wavelength decreases, and
calculate the first current value and the second current value from the average current value and the current value difference and control the first semiconductor laser in such a way that the first current value is used when the third pulse laser light is output at the first target wavelength and the second current value is used when the third pulse laser light is output at the second target wavelength.

2. The laser apparatus according to claim 1,
wherein the processor is further configured to control a temperature of the first semiconductor laser in such a way that the average current value becomes a reference current value of the current flowing through the first semiconductor laser.

3. The laser apparatus according to claim 1,
wherein the processor is further configured to control a temperature of the first semiconductor laser in such a way that the center wavelength becomes the target center wavelength based on a relationship between the temperature of the first semiconductor laser and the wavelength of the third pulse laser light.

4. The laser apparatus according to claim 3,
wherein the processor is configured to determine the relationship between the temperature of the first semiconductor laser and the wavelength of the third pulse laser light in a form of an approximate straight line.

5. The laser apparatus according to claim 3,
wherein the processor is configured to determine the relationship between the temperature of the first semiconductor laser and the wavelength of the third pulse laser light in a form of an approximate curve.

6. The laser apparatus according to claim 1,
wherein the wavelength conversion system includes a first nonlinear crystal and an actuator, and
the processor is configured to control the actuator in such a way that the first nonlinear crystal achieves phase matching at the target center wavelength.

7. The laser apparatus according to claim 6,
wherein the actuator is a rotary stage, and is configured to control an angle of incidence of the first pulse laser light to be incident on the first nonlinear crystal.

8. The laser apparatus according to claim 6,
wherein the actuator is a heater, and is configured to control a temperature of the first nonlinear crystal.

9. The laser apparatus according to claim 1,
wherein the wavelength conversion system includes
a first nonlinear crystal, and
a rotary stage configured to rotate the first nonlinear crystal, and
the processor is configured to control the rotary stage in such a way that a wavelength at which wavelength conversion efficiency is maximized becomes the target wavelength.

10. The laser apparatus according to claim 1,
wherein the wavelength conversion system is configured to output the second pulse laser light that is first harmonic light of the first pulse laser light.

11. The laser apparatus according to claim 1,
further comprising a solid-state laser apparatus configured to output fourth pulse laser light, and
the wavelength conversion system is configured to perform sum frequency operation on the first pulse laser light and the fourth pulse laser light and output the resultant second pulse laser light.

12. The laser apparatus according to claim 11,
wherein the solid-state laser apparatus includes
a second semiconductor laser configured to output second continuous-wave laser light,
a second amplifier configured to pulse and amplify the second laser light and output resultant fifth pulse laser light, and
a second nonlinear crystal configured to receive the fifth pulse laser light as an input and output second harmonic light thereof that is the fourth pulse laser light.

13. The laser apparatus according to claim 1,
wherein the first semiconductor laser is at least one of a distributed feedback semiconductor laser, a distributed Bragg reflector semiconductor laser, and a sampled grating distributed Bragg reflector semiconductor laser.

14. The laser apparatus according to claim 1,
wherein the first semiconductor laser is a distributed Bragg reflector semiconductor laser, and
the processor is configured to change the wavelength of the laser light from the first semiconductor laser by controlling a current caused to flow through a phase adjustment region of the distributed Bragg reflector semiconductor laser.

15. The laser apparatus according to claim 1,
wherein the first semiconductor laser is a sampled grating distributed Bragg reflector semiconductor laser, and
the processor is configured to change the wavelength of the laser light from the first semiconductor laser by controlling a current caused to flow through a phase adjustment region of the sampled grating distributed Bragg reflector semiconductor laser.

16. A method for manufacturing electronic devices, the method comprising:
generating third pulse laser light by using a laser apparatus;
outputting the third pulse laser light to an exposure apparatus; and
exposing a photosensitive substrate to the third pulse laser light in the exposure apparatus to manufacture the electronic devices,
the laser apparatus including
a first wavelength variable semiconductor laser configured to output first continuous-wave laser light,
a first amplifier configured to pulse and amplify the first laser light and output first pulse laser light,
a wavelength conversion system configured to convert a wavelength of the first pulse laser light and output resultant second pulse laser light,
an excimer amplifier configured to amplify the second pulse laser light and output the third pulse laser light,
a monitor module configured to measure a wavelength of the third pulse laser light, and
a processor configured to change a target wavelength of the third pulse laser light alternately to a first target wavelength and a second target wavelength longer than the first target wavelength,
calculate a center wavelength that is an average of a measured value of the wavelength of the third pulse laser light output at the first target wavelength and a measured value of the wavelength of the third pulse laser light output at the second target wavelength and a wavelength difference that is a difference between the measured values,
calculate an average current value that is an average of a first current value of a current flowing through the first semiconductor laser operating at the first target wavelength and a second current value of the current flowing through the first semiconductor laser operating at the second target wavelength in such a way that a difference between the center wavelength and a target center wavelength that is an average of the first target wavelength and the second target wavelength decreases,
calculate a current value difference that is a difference between the first current value and the second current value in such a way that a difference between the wavelength difference and a target wavelength difference that is a difference between the first target wavelength and the second target wavelength decreases, and
calculate the first current value and the second current value from the average current value and the current value difference and control the first semiconductor laser in such a way that the first current value is used when the third pulse laser light is output at the first target wavelength and the second current value is used when the third pulse laser light is output at the second target wavelength.

17. A laser apparatus comprising:
a first wavelength variable semiconductor laser configured to output first continuous-wave laser light;
a first amplifier configured to pulse and amplify the first laser light and output first pulse laser light;
a wavelength conversion system configured to convert a wavelength of the first pulse laser light and output resultant second pulse laser light;
an excimer amplifier configured to amplify the second pulse laser light and output resultant third pulse laser light;
a monitor module configured to measure a wavelength of the third pulse laser light; and
a processor configured to change a target wavelength of the third pulse laser light alternately to a first target wavelength and a second target wavelength longer than the first target wavelength,
calculate a center wavelength that is an average of a measured value of the wavelength of the third pulse laser light output at the first target wavelength and a measured value of the wavelength of the third pulse laser light output at the second target wavelength and a wavelength difference that is a difference between the measured values,
calculate a current value difference that is a difference between a first current value of a current flowing through the first semiconductor laser operating at the first target wavelength and a second current value of the current flowing through the first semiconductor laser operating at the second target wavelength in such a way that a difference between the wavelength difference and a target wavelength difference that is a difference between the first target wavelength and the second target wavelength decreases,
calculate the first current value and the second current value from a reference current value of the current flowing through the first semiconductor laser and the current value difference and control the first semiconductor laser in such a way that the first current value is used when the third pulse laser light is output at the first target wavelength and the second current value is used when the third pulse laser light is output at the second target wavelength, and
control a temperature of the first semiconductor laser in such a way that the center wavelength becomes a target center wavelength that is an average of the first target wavelength and the second target wavelength.

18. The laser apparatus according to claim 17,
wherein the first current value is a value as a result of subtraction of half the current value difference from the reference current value, and
the second current value is a value as a result of addition of half the current value difference to the reference current value.

19. A method for manufacturing electronic devices, the method comprising:
generating third pulse laser light by using a laser apparatus;
outputting the third pulse laser light to an exposure apparatus; and
exposing a photosensitive substrate to the third pulse laser light in the exposure apparatus to manufacture the electronic devices,
the laser apparatus including
a first wavelength variable semiconductor laser configured to output first continuous-wave laser light,
a first amplifier configured to pulse and amplify the first laser light and output first pulse laser light,
a wavelength conversion system configured to convert a wavelength of the first pulse laser light and output resultant second pulse laser light,
an excimer amplifier configured to amplify the second pulse laser light and output the third pulse laser light,
a monitor module configured to measure a wavelength of the third pulse laser light, and
a processor configured to change a target wavelength of the third pulse laser light alternately to a first target wavelength and a second target wavelength longer than the first target wavelength,
calculate a center wavelength that is an average of a measured value of the wavelength of the third pulse laser light output at the first target wavelength and a measured value of the wavelength of the third pulse laser light output at the second target wavelength and a wavelength difference that is a difference between the measured values,
calculate a current value difference that is a difference between a first current value of a current flowing through the first semiconductor laser operating at the first target wavelength and a second current value of the current flowing through the first semiconductor laser operating at the second target wavelength in such a way that a difference between the wavelength difference and a target wavelength difference that is a difference between the first target wavelength and the second target wavelength decreases,
calculate the first current value and the second current value from a reference current value of the current flowing through the first semiconductor laser and the current value difference and control the first semiconductor laser in such a way that the first current value is used when the third pulse laser light is output at the first target wavelength and the second current value is used when the third pulse laser light is output at the second target wavelength, and
control a temperature of the first semiconductor laser in such a way that the center wavelength becomes a target center wavelength that is an average of the first target wavelength and the second target wavelength.
